(19) United States
(12) Patent Application Publication
(10) Pub. No.: US 2024/0387370 A1
(43) Pub. Date: Nov. 21, 2024

(54) THREE-DIMENSIONAL MEMORY DEVICE CONTAINING OVERLYING THIN FILM TRANSISTOR CONTROL CIRCUIT AND METHOD OF MAKING THEREOF

(71) Applicant: WESTERN DIGITAL TECHNOLOGIES, INC.,, SAN JOSE, CA (US)

(72) Inventors: Satoru MAYUZUMI, Cupertino, CA (US); Sudarshan NARAYANAN, San Jose, CA (US); Mohan DUNGA, Santa Clara, CA (US)

(21) Appl. No.: 18/361,575

(22) Filed: Jul. 28, 2023

Related U.S. Application Data
(60) Provisional application No. 63/502,720, filed on May 17, 2023.

(51) Int. Cl. H01L 23/528; G11C 16/04; H01L 23/522; H10B 41/10; H10B 41/27; H10B 41/35; H10B 41/41; H10B 43/10; H10B 43/27; H10B 43/35; H10B 43/40

(52) U.S. Cl. CPC H01L 23/5283; G11C 16/0483; H01L 23/5226; H10B 41/10; H10B 41/27; H10B 41/35; H10B 41/41; H10B 43/10; H10B 43/27; H10B 43/35; H10B 43/40

(57) ABSTRACT

A semiconductor structure includes a memory die and a logic die. The memory die includes a three-dimensional memory device that contains an alternating stack of insulating layers and electrically conductive layers, memory openings vertically extending through the alternating stack, and memory opening fill structures located in the two-dimensional array of memory openings, where each of the memory opening fill structures includes a respective vertical semiconductor channel, a respective drain region, and a vertical stack of memory elements located at levels of the electrically conductive layers, memory-side bonding pads, and a first peripheral circuit including first thin film transistors located between the three-dimensional memory device and the memory-side bonding pads. The logic die includes a logic-side substrate, logic-side bonding pads bonded to the memory-side bonding pads, and a second peripheral circuit located between the logic-side substrate and the logic-side bonding pads.

### FIELD

The present disclosure relates generally to the field of semiconductor devices, and particularly to a three-dimensional memory device including an overlying thin film transistor control circuit and methods of manufacturing the same.

### BACKGROUND

Three-dimensional vertical NAND strings having one bit per cell are disclosed in an article by T. Endoh et al., titled “Novel Ultra High Density Memory With A Stacked-Surrounding Gate Transistor (S-SGT) Structured Cell”, IEDM Proc. (2001) 33-36.

### SUMMARY

According to an aspect of the present disclosure, a semiconductor structure includes a memory die and a logic die. The memory die includes a three-dimensional memory device that contains an alternating stack of insulating layers and electrically conductive layers, memory openings vertically extending through the alternating stack, and memory opening fill structures located in the two-dimensional array of memory openings, where each of the memory opening fill structures includes a respective vertical semiconductor channel, a respective drain region, and a vertical stack of memory elements located at levels of the electrically conductive layers, memory-side bonding pads, and a first peripheral circuit including first thin film transistors located between the three-dimensional memory device and the memory-side bonding pads. The logic die includes a logic-side substrate, logic-side bonding pads bonded to the memory-side bonding pads, and a second peripheral circuit located between the logic-side substrate and the logic-side bonding pads.

According to another aspect of the present disclosure, a method of forming a semiconductor structure includes providing a memory die, comprising a three-dimensional memory device that comprises an alternating stack of insulating layers and electrically conductive layers, memory openings vertically extending through the alternating stack, and memory opening fill structures located in the two-dimensional array of memory openings, wherein each of the memory opening fill structures comprises a respective vertical semiconductor channel, a respective drain region, and a vertical stack of memory elements located at levels of the electrically conductive layers; memory-side bonding pads; and a first peripheral circuit comprising first thin film transistors located between the three-dimensional memory device and the memory-side bonding pads. The method also includes providing a logic die, comprising a logic-side substrate; logic-side bonding pads; and a second peripheral circuit located between the logic-side substrate and the logic-side bonding pads. The method also includes bonding the logic side bonding pads to the memory-side bonding pads.

### BRIEF DESCRIPTION OF THE DRAWINGS

FIG. 1 is a schematic vertical cross-sectional view of an exemplary structure after formation of optional semiconductor devices, optional lower-level metal interconnect structures, a semiconductor material layer, and an alternating stack of insulating layers and sacrificial material layers according to an embodiment of the present disclosure.

FIG. 2 is a schematic vertical cross-sectional view of the exemplary structure after formation of stepped terraces and a retro-stepped dielectric material portion according to an embodiment of the present disclosure.

FIG. 3A is a schematic vertical cross-sectional view of the exemplary structure after formation of memory openings and support openings according to an embodiment of the present disclosure.

FIG. 3B is a top-down view of the exemplary structure of FIG. 3A. The vertical plane A-A′ is the plane of the cross-section for FIG. 3A.

FIG. 4 is a schematic vertical cross-sectional view of the exemplary structure after formation of support pillar structures according to an embodiment of the present disclosure.

FIGS. 5A-5D are sequential schematic vertical cross-sectional views of a memory opening within the exemplary structure during formation of a memory opening fill structure according to an embodiment of the present disclosure.

FIG. 6 is a schematic vertical cross-sectional view of the exemplary structure after formation of memory opening fill structures and support pillar structures according to an embodiment of the present disclosure.

FIG. 7A is a schematic vertical cross-sectional view of the exemplary structure after formation of a contact-level dielectric layer, lateral isolation trenches, and source regions according to an embodiment of the present disclosure.

FIG. 7B is a partial see-through top-down view of the exemplary structure of FIG. 7A. The vertical plane A-A′ is the plane of the schematic vertical cross-sectional view of FIG. 7A.

FIG. 8 is a vertical cross-sectional view of the exemplary structure after formation of a source-level cavity according to an embodiment of the present disclosure.

FIG. 9 is a vertical cross-sectional view of the exemplary structure after formation of a source contact layer according to an embodiment of the present disclosure.

FIG. 10 is a vertical cross-sectional view of the exemplary structure after formation of laterally-extending cavities according to an embodiment of the present disclosure.

FIG. 11 is a vertical cross-sectional view of the exemplary structure after formation of electrically conductive layers according to an embodiment of the present disclosure.

FIG. 12A is a vertical cross-sectional view of the exemplary structure after formation of lateral isolation trench fill structures and contact via structures according to an embodiment of the present disclosure.

FIG. 12B is a top-down view of the exemplary structure of FIG. 12A. The vertical plane A-A′ is the cut plane of the vertical cross-sectional view of FIG. 12A.

FIG. 13A is a vertical cross-sectional view of the exemplary structure after formation of first metal interconnect structures including connection-level via structures and bit-line-level metal lines according to an embodiment of the present disclosure.

FIG. 13B is a top-down view of the exemplary structure of FIG. 13A. The vertical plane A-A′ is the cut plane of the vertical cross-sectional view of FIG. 13A.

FIGS. 14A-14H are sequential vertical cross-sectional view of an upper portion of the exemplary structure during formation of a planar dielectric spacer layer, first thin film transistors, second metal interconnect structures, second thin film transistors, third metal interconnect structures, memory-side dielectric material layers and memory-side metal interconnect structures, and memory-side bonding pads according to an embodiment of the present disclosure.

FIGS. 14I, 14J and 14K are vertical cross-sectional views of upper portions of alternative configurations of the exemplary structure shown in FIG. 14F.

FIG. 15 is a vertical cross-sectional view of an alternative configuration of an upper portion of the exemplary structure after formation of a planar dielectric spacer layer, first thin film transistors, second metal interconnect structures, memory-side dielectric material layers and memory-side metal interconnect structures, and memory-side bonding pads according to an embodiment of the present disclosure.

FIG. 16 is a vertical cross-sectional view of another alternative configuration of an upper portion of the exemplary structure after formation of a planar dielectric spacer layer, first thin film transistors, second metal interconnect structures, second thin film transistors, third metal interconnect structures, memory-side dielectric material layers and memory-side metal interconnect structures, and memory-side bonding pads according to an embodiment of the present disclosure.

FIG. 17 is a vertical cross-sectional view of another alternative configuration of the exemplary structure after formation of a planar dielectric spacer layer, first thin film transistors, second metal interconnect structures, memory-side dielectric material layers and memory-side metal interconnect structures, and memory-side bonding pads according to an embodiment of the present disclosure.

FIG. 18 is a vertical cross-sectional view of a memory die in various configurations of the exemplary structure at the processing steps of FIGS. 14H, 15, 16, and 17.

FIG. 19 is a vertical cross-sectional view of a logic die according to an embodiment of the present disclosure.

FIG. 20 is a vertical cross-sectional view of the exemplary structure after attaching the logic die to the memory die according to an embodiment of the present disclosure.

FIG. 21 is a vertical cross-sectional view of the exemplary structure after removal of the carrier substrate according to an embodiment of the present disclosure.

### DETAILED DESCRIPTION

As discussed above, embodiments of the present disclosure are directed to a three-dimensional memory device including an overlying thin film transistor control circuit and methods of manufacturing the same, the various aspects of which are described below. In one embodiment, the memory openings may be elongated along the nearest neighbor distance.

The drawings are not drawn to scale. Multiple instances of an element may be duplicated where a single instance of the element is illustrated, unless absence of duplication of elements is expressly described or clearly indicated otherwise. Ordinals such as “first,” “second,” and “third” are employed merely to identify similar elements, and different ordinals may be employed across the specification and the claims of the instant disclosure. The term “at least one” element refers to all possibilities including the possibility of a single element and the possibility of multiple elements.

The same reference numerals refer to the same element or similar element. Unless otherwise indicated, elements having the same reference numerals are presumed to have the same composition and the same function. Unless otherwise indicated, a “contact” between elements refers to a direct contact between elements that provides an edge or a surface shared by the elements. If two or more elements are not in direct contact with each other or among one another, the two elements are “disjoined from” each other or “disjoined among” one another. As used herein, an element located “on” a second element can be located on the exterior side of a surface of the second element or on the interior side of the second element. As used herein, an element is located “directly on” a second element if there exist a physical contact between a surface of the element and a surface of the second element. As used herein, an element is “electrically connected to” a second element if there exists a conductive path consisting of at least one conductive material between the element and the second element. As used herein, a “prototype” structure or an “in-process” structure refers to a transient structure that is subsequently modified in the shape or composition of at least one component therein.

As used herein, a “layer” refers to a material portion including a region having a thickness. A layer may extend over the entirety of an underlying or overlying structure, or may have an extent less than the extent of an underlying or overlying structure. Further, a layer may be a region of a homogeneous or inhomogeneous continuous structure that has a thickness less than the thickness of the continuous structure. For example, a layer may be located between any pair of horizontal planes between, or at, a top surface and a bottom surface of the continuous structure. A layer may extend horizontally, vertically, and/or along a tapered surface. A substrate may be a layer, may include one or more layers therein, or may have one or more layer thereupon, thereabove, and/or therebelow.

Generally, a semiconductor die, or a semiconductor package, can include a memory chip. Each semiconductor package contains one or more dies (for example one, two, or four). The die is the smallest unit that can independently execute commands or report status. Each die contains one or more planes (typically one or two). Identical, concurrent operations can take place on each plane, although with some restrictions. Each plane contains a number of blocks, which are the smallest unit that can be erased by in a single erase operation. Each block contains a number of pages, which are the smallest unit that can be programmed, i.e., a smallest unit on which a read operation can be performed.

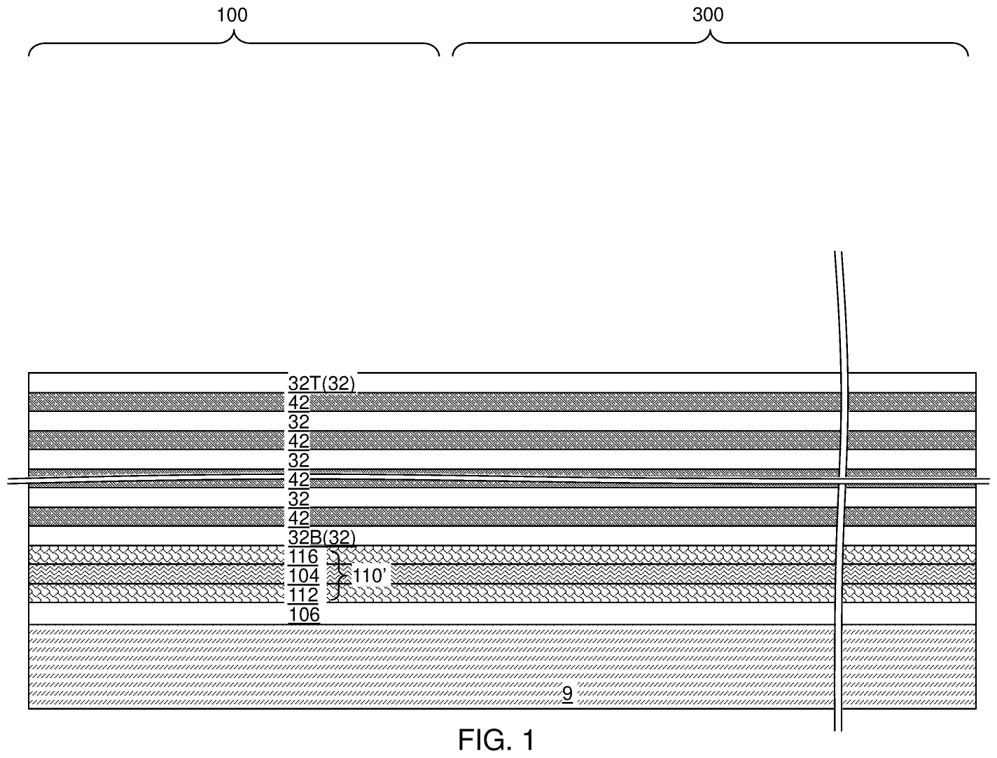

Referring to FIG. 1, an exemplary structure according to an embodiment of the present disclosure is illustrated. The exemplary structure comprises a substrate 9, which may be a semiconductor substrate or a conductive substrate. For example, the substrate 9 may comprise a commercially available silicon wafer. Alternatively, the substrate 9 may comprise a carrier substrate 9 which is formed of any material that may be removed selective the materials of insulating layers 32 and dielectric material portions to be subsequently formed.

An optional insulating material layer can be formed on a top surface of the carrier substrate 9. The insulating material layer can be subsequently employed as a stopping material layer for a process that removes the carrier substrate 9, and is herein referred to as a stopper insulating layer 106, or as a backside pad dielectric layer. If a polishing process such as a chemical mechanical polishing process is employed to subsequently remove the carrier substrate 9, the stopper material layer 106 may be subsequently employed as a polishing stopper material layer. If an etch process such as a wet etch process is employed to subsequently remove the carrier substrate 9, the stopper material layer 106 may be subsequently employed as an etch stop material layer. In one embodiment, the stopper insulating layer 106 comprises a dielectric material such as undoped silicate glass, a doped silicate glass, or silicon nitride. The thickness of the stopper insulating layer 106 may be in a range from 50 nm to 600 nm, such as from 100 nm to 300 nm, although lesser and greater thicknesses may also be employed.

Optional in-process source-level material layers 110′ can be formed over the stopper insulating layer 106. The in-process source-level material layers 110′ may include various layers that are subsequently modified to form source-level material layers. The source-level material layers, upon formation, include a source contact layer that functions as a common source region for vertical field effect transistors of a three-dimensional memory device. In one embodiment, the in-process source-level material layers 110′ may include, from bottom to top, a lower source-level semiconductor layer 112, an optional lower sacrificial liner 103, a source-level sacrificial layer 104, an optional upper sacrificial liner 105, and an upper source-level semiconductor layer 116.

The lower source-level semiconductor layer 112 and the upper source-level semiconductor layer 116 may include a doped semiconductor material such as doped polysilicon or doped amorphous silicon. The conductivity type of the lower source-level semiconductor layer 112 and the upper source-level semiconductor layer 116 may be the opposite of the conductivity of vertical semiconductor channels to be subsequently formed. For example, if the vertical semiconductor channels to be subsequently formed have a doping of a first conductivity type, the lower source-level semiconductor layer 112 and the upper source-level semiconductor layer 116 have a doping of a second conductivity type that is the opposite of the first conductivity type. The thickness of each of the lower source-level semiconductor layer 112 and the upper source-level semiconductor layer 116 may be in a range from 10 nm to 300 nm, such as from 20 nm to 150 nm, although lesser and greater thicknesses may also be used.

The source-level sacrificial layer 104 includes a sacrificial material that may be removed selective to the lower sacrificial liner 103 (or selective to the lower source-level semiconductor layer 112) and the upper sacrificial liner 105 (or selective to the upper source-level semiconductor layer 116). In one embodiment, the source-level sacrificial layer 104 may include a semiconductor material such as undoped amorphous silicon or a silicon-germanium alloy with an atomic concentration of germanium greater than 20%. The thickness of the source-level sacrificial layer 104 may be in a range from 30 nm to 400 nm, such as from 60 nm to 200 nm, although lesser and greater thicknesses may also be used. The lower sacrificial liner 103 (if present) and the upper sacrificial liner 105 (if present) include materials that may function as an etch stop material during removal of the source-level sacrificial layer 104. For example, the lower sacrificial liner 103 and the upper sacrificial liner 105 may include silicon oxide, silicon nitride, and/or a dielectric metal oxide. In one embodiment, each of the lower sacrificial liner 103 and the upper sacrificial liner 105 may include a silicon oxide layer having a thickness in a range from 2 nm to 30 nm, although lesser and greater thicknesses may also be used.

An alternating stack of first material layers and second material layers can be formed over the in-process source-level material layers 110′. The first material layers may be insulating layers, and the second material layers may be spacer material layers. In one embodiment, the spacer material layers may comprise sacrificial material layers 42. In this case, an alternating stack (32, 42) of insulating layers 32 and sacrificial material layers 42 can be formed over the in-process source-level material layers 110′. The insulating layers 32 comprise an insulating material such as undoped silicate glass or a doped silicate glass, and the sacrificial material layers 42 comprise a sacrificial material, such as silicon nitride or a silicon-germanium alloy. In one embodiment, the insulating layers 32 (i.e., the first material layers) may comprise silicon oxide layers, and the sacrificial material layers 42 (i.e., the second material layers) may comprise silicon nitride layers. The alternating stack (32, 42) may comprise multiple repetitions of a unit layer stack including an insulating layer 32 and a sacrificial material layer 42. The total number of repetitions of the unit layer stack within the alternating stack (32, 42) may be, for example, in a range from 8 to 1,024, such as from 32 to 256, although lesser and greater number of repetitions may also be employed. The topmost one of the insulating layers 32 is hereafter referred to as a topmost insulating layer 32T. The bottommost one of the insulating layers 32 is an insulating layer 32 that is most proximal to the carrier substrate 9 is herein referred to as a bottommost insulating layer 32B.

Each of the insulating layers 32 other than the topmost insulating layer 32 may have a thickness in a range from 20 nm to 100 nm, such as from 30 nm to 60 nm, although lesser and greater thicknesses may also be employed. Each of the sacrificial material layers 42 may have a thickness in a range from 20 nm to 100 nm, such as from 30 nm to 60 nm, although lesser and greater thicknesses may also be employed. In one embodiment, the topmost insulating layer 32 may have a thickness of about one half of the thickness of other insulating layers 32.

The exemplary structure comprises a memory array region 100 in which a three-dimensional array of memory elements is to be subsequently formed, and a contact region 300 in which layer contact via structures contacting word lines are to be subsequently formed.

While an embodiment is described in which the spacer material layers are formed as sacrificial material layers 42, the spacer material layers may be formed as electrically conductive layers in an alternative embodiment. Generally, spacer material layers of the present disclosure may be formed as, or may be subsequently replaced at least partly with, electrically conductive layers.

In an alternative embodiment, driver circuit semiconductor devices (e.g., transistors) may be formed over the substrate 9 next to the alternating stack (32, 42) or underneath the alternating stack (32, 42). In yet another alternative embodiment, the in-process source-level material layers 110′ may be omitted, in case the substrate 9 is a carrier substrate which is later removed and a top source contact layer is formed on an exposed surface of the memory device.

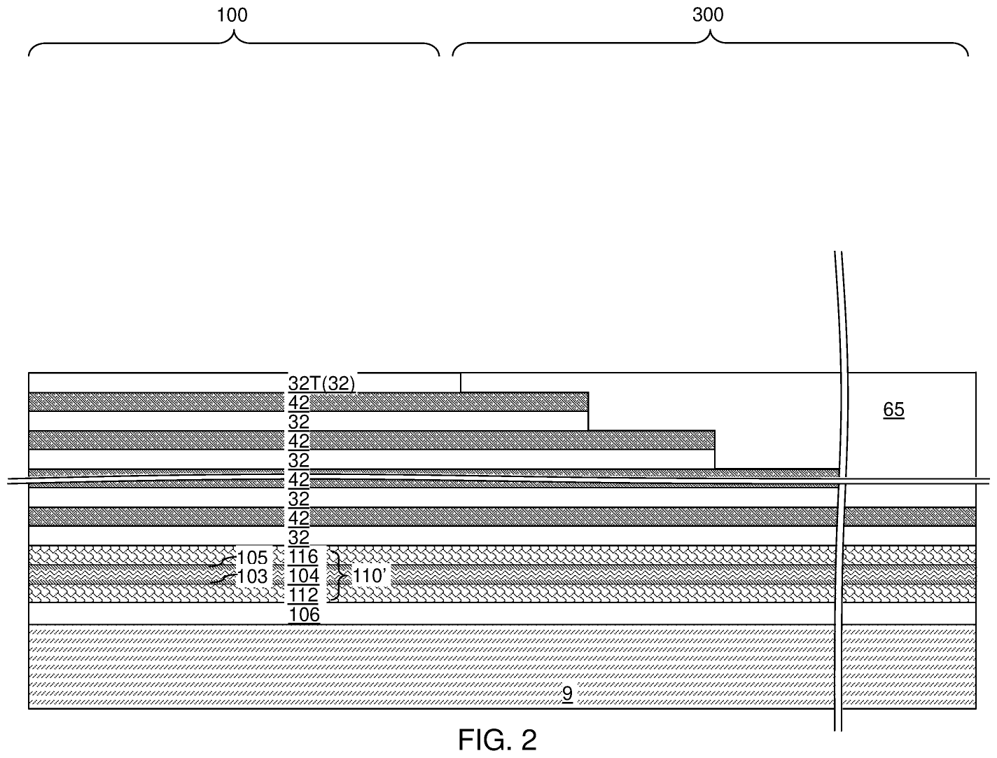

Referring to FIG. 2, optional stepped surfaces are formed in the contact region 300. As used herein, “stepped surfaces” refer to a set of surfaces that include at least two horizontal surfaces and at least two vertical surfaces such that each horizontal surface is adjoined to a first vertical surface that extends upward from a first edge of the horizontal surface, and is adjoined to a second vertical surface that extends downward from a second edge of the horizontal surface. A stepped cavity is formed within the volume from which portions of the alternating stack (32, 42) are removed through formation of the stepped surfaces. A “stepped cavity” refers to a cavity having stepped surfaces.

The stepped cavity can have various stepped surfaces such that the horizontal cross-sectional shape of the stepped cavity changes in steps as a function of the vertical distance from the top surface of the in-process source-level material layers 110′. In one embodiment, the stepped cavity can be formed by repetitively performing a set of processing steps. The set of processing steps can include, for example, an etch process of a first type that vertically increases the depth of a cavity by one or more levels, and an etch process of a second type that laterally expands the area to be vertically etched in a subsequent etch process of the first type. As used herein, a “level” of a structure including alternating plurality is defined as the relative position of a pair of a first material layer and a second material layer within the structure.

Each sacrificial material layer 42 other than a topmost sacrificial material layer 42 within the alternating stack (32, 42) laterally extends farther than any overlying sacrificial material layer 42 within the alternating stack (32, 42) in the terrace region. The stepped surfaces of the alternating stack (32, 42) continuously extend from a bottommost layer within the alternating stack (32, 42) (such as the bottommost insulating layer 32B) to a topmost layer within the alternating stack (32, 42) (such as the topmost insulating layer 32T).

A retro-stepped dielectric material portion 65 (i.e., an insulating fill material portion) can be formed in the stepped cavity by deposition of a dielectric material therein. For example, a dielectric material such as silicon oxide can be deposited in the stepped cavity. Excess portions of the deposited dielectric material can be removed from above the top surface of the topmost insulating layer 32T, for example, by chemical mechanical planarization (CMP). The remaining portion of the deposited dielectric material filling the stepped cavity constitutes the retro-stepped dielectric material portion 65. As used herein, a “retro-stepped” element refers to an element that has stepped surfaces and a horizontal cross-sectional area that increases monotonically as a function of a vertical distance from a top surface of a substrate on which the element is present. If silicon oxide is employed for the retro-stepped dielectric material portion 65, the silicon oxide of the retro-stepped dielectric material portion 65 may, or may not, be doped with dopants such as B, P, and/or F.

Optionally, drain-select-level isolation structures (not shown) can be formed through the topmost insulating layer 32T and a subset of the sacrificial material layers 42 located at drain-select-levels. The drain-select-level isolation structures can be formed, for example, by forming drain-select-level lateral isolation trenches and filling the drain-select-level lateral isolation trenches with a dielectric material such as silicon oxide. Excess portions of the dielectric material can be removed from above the top surface of the topmost insulating layer 32T.

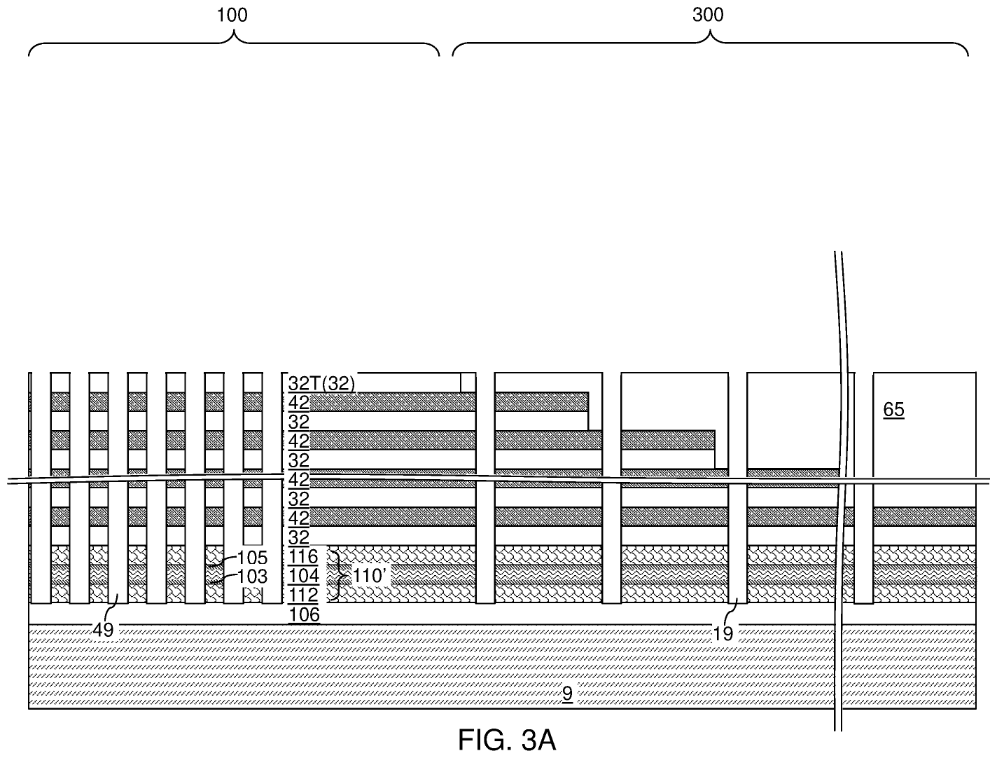

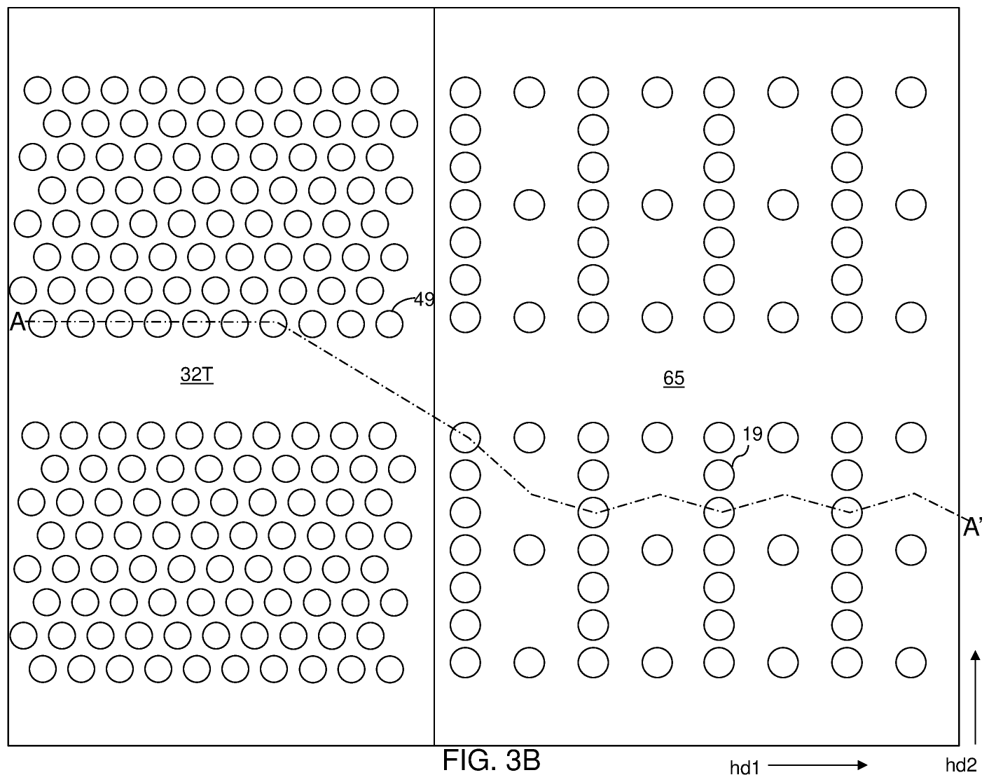

Referring to FIGS. 3A and 3B, an etch mask layer (not shown) can be formed over the alternating stack (32, 42), and can be lithographically patterned to form various openings therein. An anisotropic etch process can be performed to transfer the pattern of the openings in the etch mask layer through the alternating stack (32, 42). Various openings can be formed through the alternating stack (32, 42). The various openings may comprise memory openings 49 that are formed in the memory array region 100 and support openings 19 that are formed in the contact region 300. Each of the memory openings 49 and the support openings 19 can vertically extend through the alternating stack (32, 42) and into the in-process source-level material layers 110′ In one embodiment, bottom surfaces of the memory openings 49 and the support openings 19 may be formed within the lower source-level semiconductor layer 112 or at an interface between the lower source-level semiconductor layer and the stopper insulating layer 106.

The support openings 19 may have a diameter in a range from 60 nm to 400 nm, such as from 120 nm to 300 nm, although lesser and greater thicknesses may be employed. The memory openings 49 may have a diameter in a range from 60 nm to 400 nm, such as from 120 nm to 300 nm, although lesser and greater thicknesses may be employed.

In one embodiment, the memory array region 100 may be laterally spaced apart from the contact region 300 along a first horizontal direction hd1. The memory openings 49 may comprise rows of memory openings 49 that are arranged along the first horizontal direction hd1 and laterally spaced apart along a second horizontal direction hd2 that is perpendicular to the first horizontal direction hd2. Multiple clusters of memory openings 49, each containing a respective two-dimensional periodic array of memory openings 49, may be formed in the memory array region 100. The clusters of memory openings 49 may be laterally spaced apart along the second horizontal direction hd2.

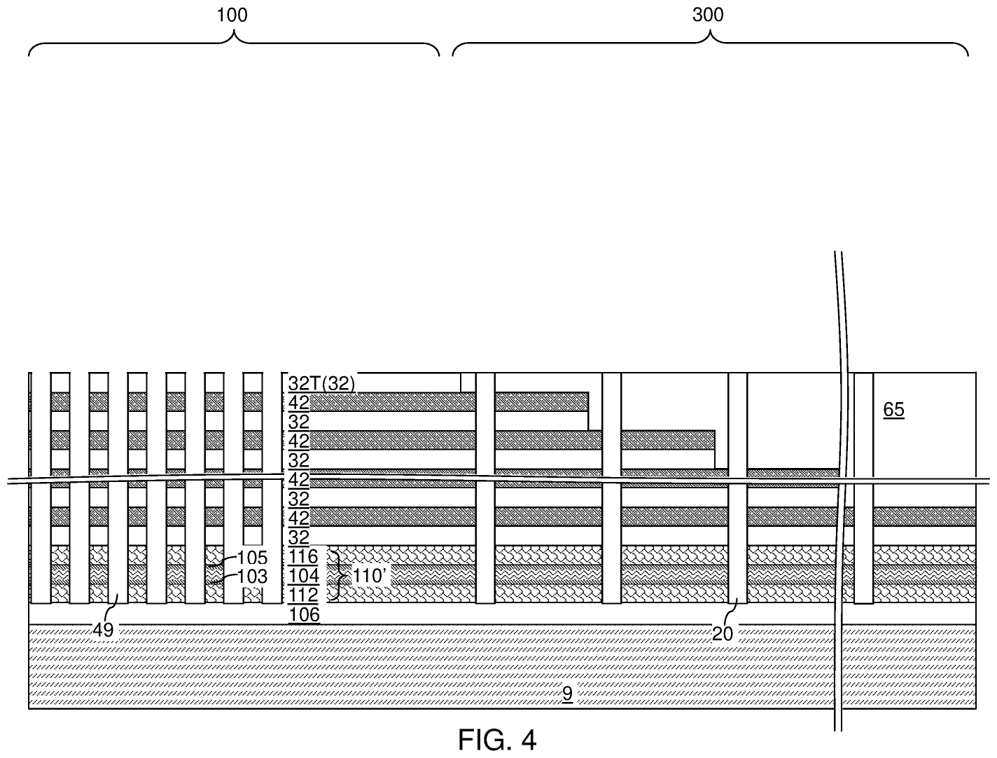

Referring to FIG. 4, an optional etch stop liner (not shown) and a sacrificial fill material (not shown) can be deposited in the memory openings 49 and the support openings. The optional etch stop liner (if present) comprises a thin dielectric material layer comprising silicon oxide, silicon nitride, or a dielectric metal oxide and having a thickness in a range from 1 nm to 6 nm. The sacrificial fill material may comprise a carbon-based material (such as amorphous carbon or diamond-like carbon), a semiconductor material (such as amorphous silicon or polysilicon), a dielectric fill material (such as borosilicate glass or organosilicate glass), or a polymer material. Excess portions of the sacrificial fill material can be removed from above the horizontal plane including the topmost layer of the alternating stack (32, 42) by a planarization process such as an etch back process. Remaining portions of the sacrificial fill material that fill the memory openings 49 and the support openings 19 constitute sacrificial memory opening fill structures (not shown) and sacrificial support opening fill structures (not shown).

A photoresist layer (not shown) can be applied over the alternating stack (32, 42) and the retro-stepped dielectric material portion 65, and can be lithographically patterned to cover the memory array region 100 without covering the contact region 300. The sacrificial support opening fill structures and portions of the optional etch stop liner in the contact region 300 can be removed selective to the materials of the retro-stepped dielectric material portion 65 and the alternating stack (32, 42). For example, an etch process or an ashing process may be employed to remove the sacrificial support opening fill structures and portions of the optional etch stop liner in the contact region 300. The photoresist layer can be subsequently removed.

A dielectric fill material, such as silicon oxide, can be deposited in the support openings 19 by a conformal deposition process. Excess portions of the dielectric fill material can be removed from above the top surface of the topmost insulating layer 32T, for example, by a recess etch process. Each portion of the dielectric fill material that fills a respective support opening 19 constitutes a support pillar structure 20, which can be employed to provide structural support to the insulating layers 32 and the retro-stepped dielectric material portion 65 during replacement of the sacrificial material layers 42 with electrically conductive layers.

Subsequently, the sacrificial memory opening fill structures and portions of the optional etch stop liner in the memory array region 100 can be removed selective to the materials of the retro-stepped dielectric material portion 65 and the alternating stack (32, 42). For example, an etch process or an ashing process may be employed to remove the sacrificial memory opening fill structures and portions of the optional etch stop liner in the memory array region 100. Voids are formed in the volumes of the memory openings 49.

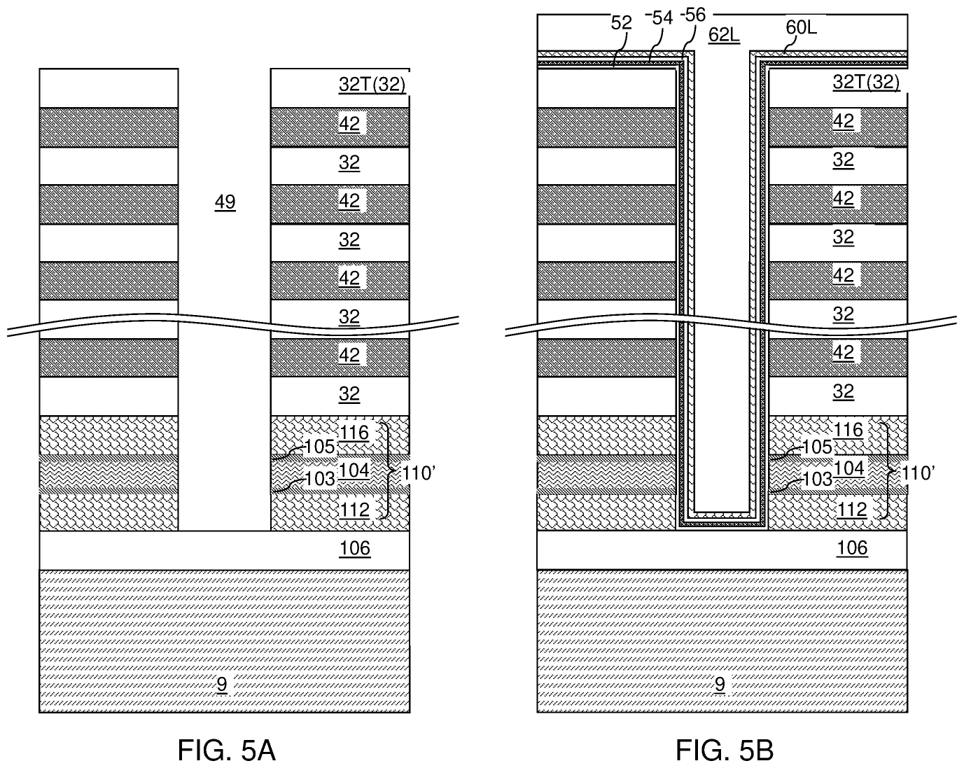

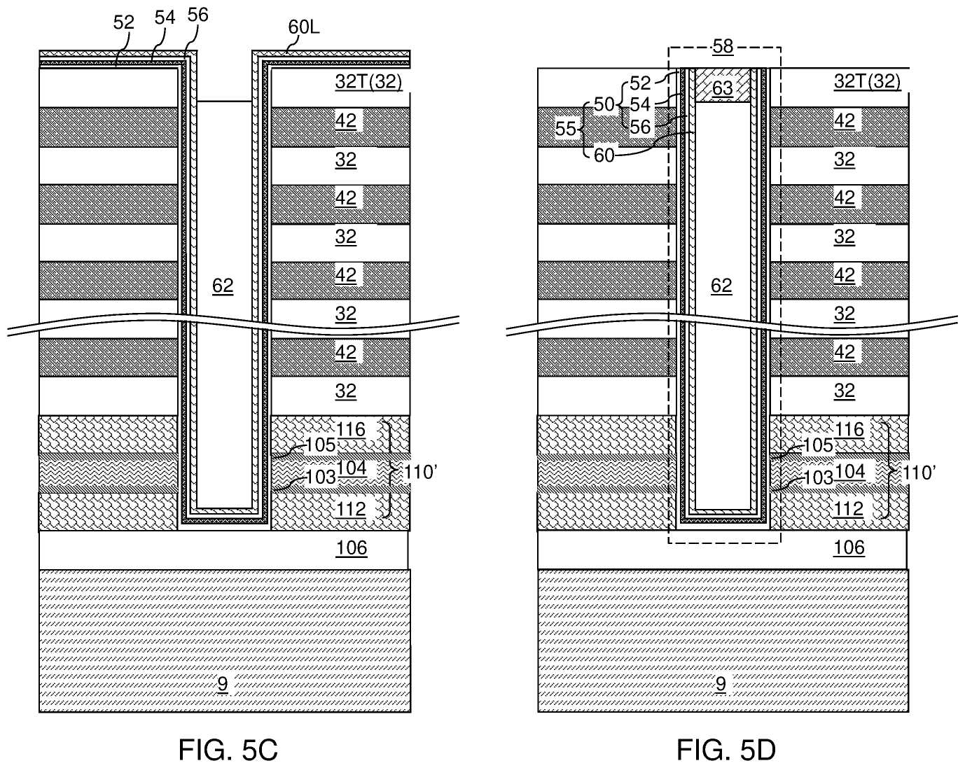

FIGS. 5A-5D are sequential schematic vertical cross-sectional views of a memory opening 49 within the exemplary structure during formation of a memory opening fill structure 58 according to an embodiment of the present disclosure.

Referring to FIG. 5A, a memory opening 49 is illustrated after the processing steps of FIG. 4.

Referring to FIG. 5B, a layer stack including a memory material layer 54 can be conformally deposited. In an illustrative example, the layer stack may comprise an optional blocking dielectric layer 52, the memory material layer 54, and an optional dielectric liner 56. The memory material layer 54 includes a memory material, i.e., a material that can store data bits therein. The memory material layer 54 may comprise a charge storage material (such as silicon nitride), a ferroelectric material, a phase change memory material, or any other memory material that can store data bits by inducing a change in the electrical resistivity, ferroelectric polarization, or any other measurable physical property. In case the memory material layer 54 comprise a charge storage material, the optional dielectric liner 56 may comprise a tunneling dielectric layer.

A semiconductor channel material layer 60L can be deposited over the layer stack (52, 54, 56) by performing a conformal deposition process. If the semiconductor channel material layer 60L is doped, the semiconductor channel material layer 60L may have a doping of a first conductivity type, which may be p-type or n-type. In one embodiment, the first semiconductor material comprises a first doped silicon material having a doping of the first conductivity type. In an illustrative example, the atomic concentration of dopants of the first conductivity type in the semiconductor channel material layer 60L may be in a range from 1.0×10¹³/cm³ to 3.0×10¹⁷/cm³, such as 1.0×10¹⁴/cm³ to 3.0×10¹⁶/cm³, although lesser and greater atomic concentrations may also be employed. A dielectric core layer 62L comprising a dielectric fill material can be deposited in remaining volumes of the memory openings 49 and over the alternating stack (32, 42).

Referring to FIG. 5C, the dielectric core layer 62L can be vertically recessed such that each remaining portion of the dielectric core layer 62L has a top surface at, or about, the horizontal plane including the bottom surface of the topmost insulating layers 32T. Each remaining portion of the dielectric core layer 62L constitutes a dielectric core 62.

Referring to FIG. 5D, a doped semiconductor material having a doping of a second conductivity type can be deposited within each recessed region above the dielectric cores 62. The second conductivity type is the opposite of the first conductivity type. For example, if the first conductivity type is p-type, the second conductivity type is n-type, and vice versa. The dopant concentration in the deposited semiconductor material can be in a range from 5.0×10¹⁸/cm³ to 2.0×10²¹/cm³, although lesser and greater dopant concentrations can also be employed. The doped semiconductor material can be, for example, doped polysilicon.

Excess portions of the deposited semiconductor material having a doping of the second conductivity type and a horizontal portion of the semiconductor channel layer 60L can be removed from above the horizontal plane including the top surface of the topmost insulating layer 32T, for example, by chemical mechanical planarization (CMP) or a recess etch process. Each remaining portion of the doped semiconductor material having a doping of the second conductivity type constitutes a drain region 63. Each remaining portion of the semiconductor channel layer 60L (which has a doping of the first conductivity type) constitutes a vertical semiconductor channel 60.

Each portion of the layer stack including the memory material layer 54 that remains in a respective memory opening 49 constitutes a memory film 50. In one embodiment, a memory film 50 may comprise an optional blocking dielectric layer 52, a memory material layer 54, and an optional dielectric liner 56. Each contiguous combination of a memory film 50 and a vertical semiconductor channel 60 constitutes a memory stack structure 55. Each combination of a memory stack structure 55, a dielectric core 62, and a drain region 63 within a memory opening 49 constitutes a memory opening fill structure 58. Each memory opening fill structure 58 comprises a respective vertical stack of memory elements, which may comprise portions of the memory material layer 54 located at levels of the sacrificial material layers 42, or generally speaking, at levels of spacer material layers that may be formed as, or may be subsequently replaced at least partly with, electrically conductive layers.

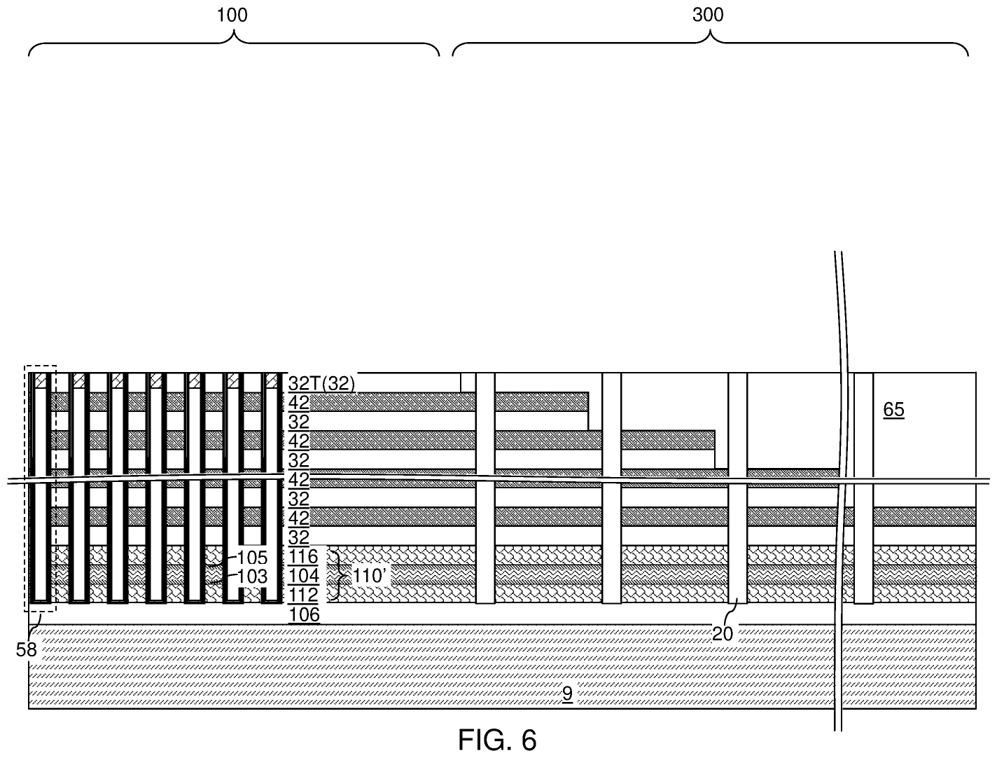

Referring to FIG. 6, the exemplary structure is illustrated after formation of memory opening fill structures 58 within the memory openings 49. Each of the memory opening fill structures 58 may comprise a respective vertical semiconductor channel 60 that is laterally surrounded by the respective vertical stack of memory elements (which may be embodied as portions of the memory film 50 located at levels of the sacrificial material layers 42 that are subsequently replaced with electrically conductive layers).

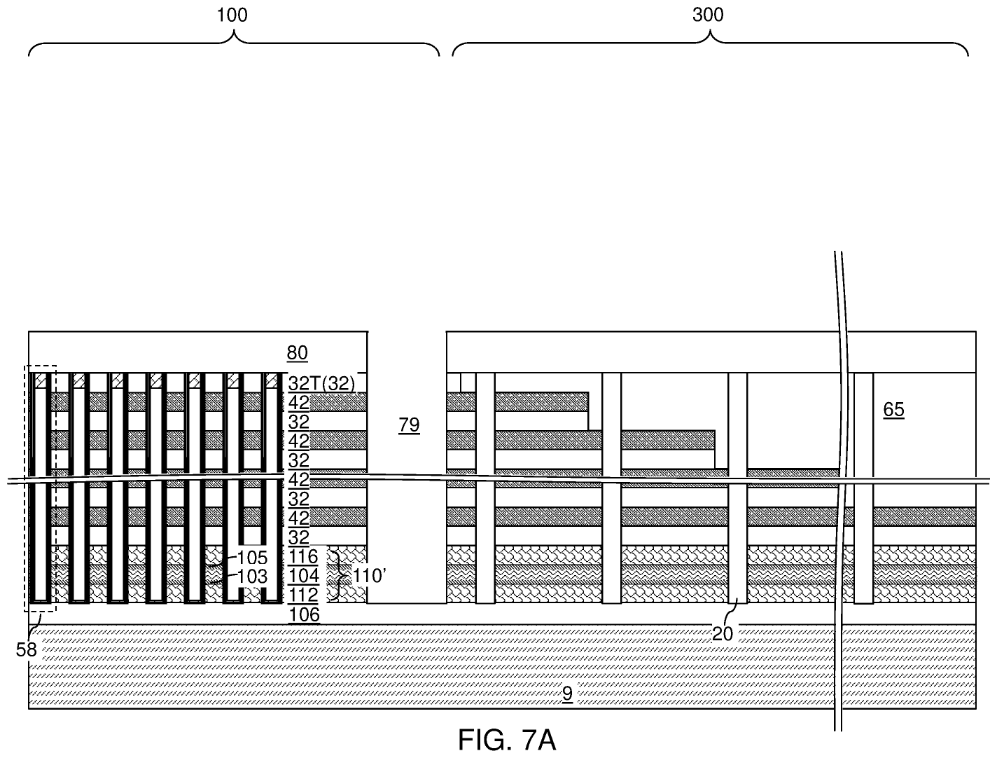

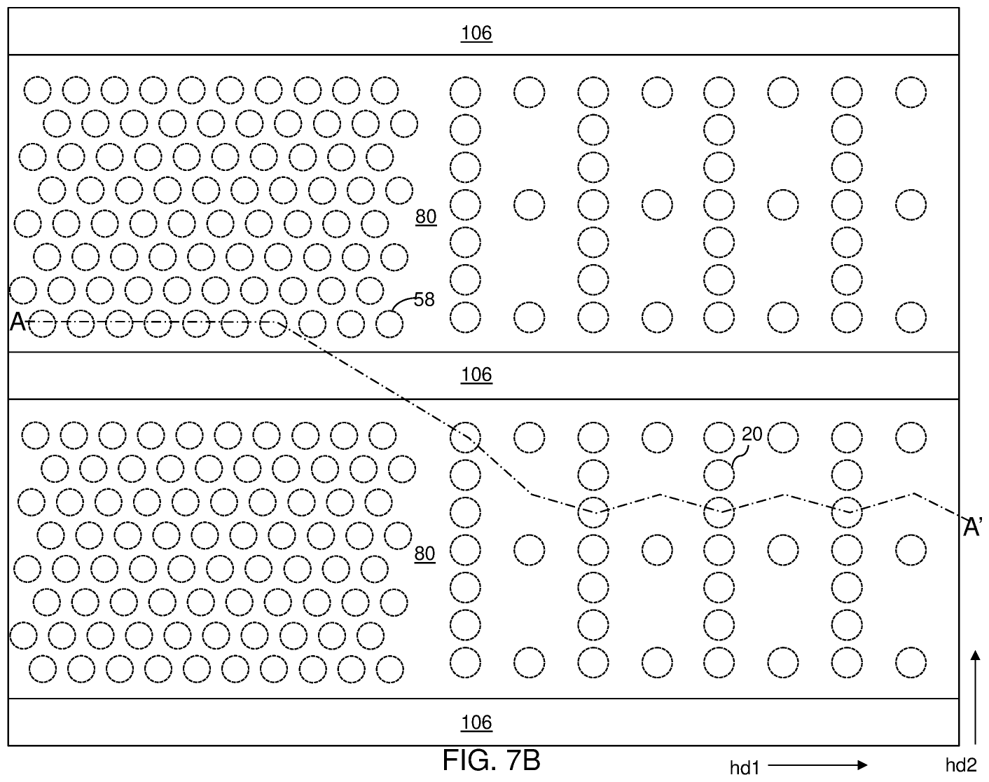

Referring to FIGS. 7A and 7B, a dielectric material such as undoped silicate glass or a doped silicate glass can be deposited over the alternating stack (32, 42) to form a contact-level dielectric layer 80. The thickness of the contact-level dielectric layer 80 may be in a range from 100 nm to 600 nm, such as from 200 nm to 400 nm, although lesser and greater thicknesses may also be employed.

A photoresist layer (not shown) can be applied over the contact-level dielectric layer 80, and can be lithographically patterned to form elongated openings that laterally extend along the first horizontal direction hd1 between neighboring clusters of memory opening fill structures 58. An anisotropic etch process can be performed to transfer the pattern of the openings in the photoresist layer through the contact-level dielectric layer 80, the alternating stack (32, 42), the stepped dielectric material portion 65, and the in-process source-level material layers 110′. Lateral isolation trenches 79 laterally extending along the first horizontal direction hd1 can be formed through the alternating stack (32, 42), the stepped dielectric material portion 65, the contact-level dielectric layer 80, and the in-process source-level material layers 110′. Each of the lateral isolation trenches 79 may comprise a respective pair of lengthwise sidewalls that are parallel to the first horizontal direction hd1 and vertically extend from the stopper insulating layer 106 to the top surface of the contact-level dielectric layer 80. A top surface of the stopper insulating layer 106 can be physically exposed underneath each lateral isolation trench 79. The photoresist layer can be subsequently removed, for example, by ashing.

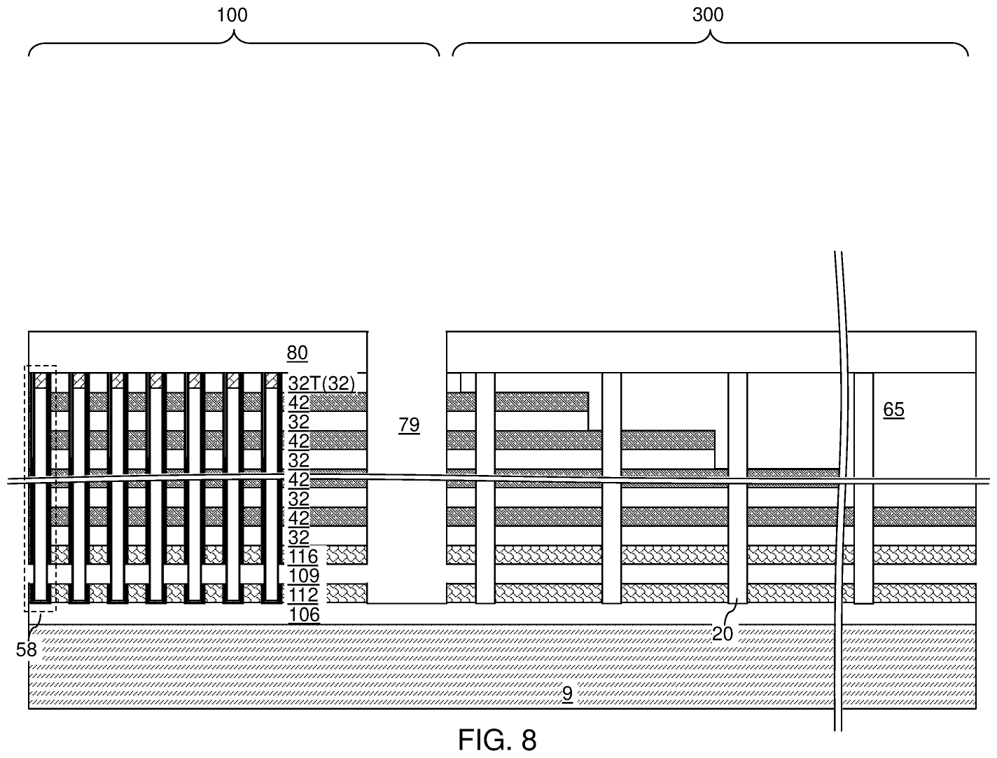

Referring to FIG. 8, an etchant that etches the material of the source-level sacrificial layer 104 selective to the materials of the alternating stack (32, 42), the contact level dielectric layer 80, the stepped dielectric material portion 65, the lower source-level semiconductor layer 112, the upper source-level semiconductor layer 116, the upper sacrificial liner 105 (if present), and the lower sacrificial liner 103 (if present) may be introduced into the lateral isolation trenches 79 by performing an isotropic etch process. For example, if the source-level sacrificial layer 104 includes undoped amorphous silicon or a silicon-germanium alloy, a wet etch process using hot trimethyl-2 hydroxyethyl ammonium hydroxide (“hot TMY”) or tetramethyl ammonium hydroxide (TMAH) may be used to remove the source-level sacrificial layer 104 selective to the alternating stack (32, 42), the contact level dielectric layer 80, the stepped dielectric material portion 65, the lower source-level semiconductor layer 112, and the upper source-level semiconductor layer 116. A source cavity 109 is formed in the volume from which the source-level sacrificial layer 104 is removed.

Wet etch chemicals such as hot TMY and TMAH are selective to doped semiconductor materials such as the p-doped semiconductor material and/or the n-doped semiconductor material of the upper source-level semiconductor layer 116 and the lower source-level semiconductor layer 112. Thus, use of selective wet etch chemicals such as hot TMY and TMAH for the wet etch process that forms the source cavity 109 provides a large process window against etch depth variation during formation of the lateral isolation trenches 79. Specifically, even if sidewalls of the upper source-level semiconductor layer 116 are physically exposed or even if a surface of the lower source-level semiconductor layer 112 is physically exposed upon formation of the source cavity 109, collateral etching of the upper source-level semiconductor layer 116 and/or the lower source-level semiconductor layer 112 is minimal, and the structural change to the exemplary structure caused by accidental physical exposure of the surfaces of the upper source-level semiconductor layer 116 and/or the lower source-level semiconductor layer 112 during manufacturing steps do not result in device failures. Each of the memory opening fill structures 58 is physically exposed to the source cavity 109. Specifically, each of the memory opening fill structures 58 includes a sidewall and that are physically exposed to the source cavity 109.

A sequence of isotropic etchants, such as wet etchants, may be applied to the physically exposed portions of the memory films 50 to sequentially etch the various component layers of the memory films 50 from outside to inside, and to physically expose cylindrical surfaces of the vertical semiconductor channels 60 at the level of the source cavity 109. The upper sacrificial liner 105 (if present) and the lower sacrificial liner 103 (if present) may be collaterally etched during removal of the portions of the memory films 50 located at the level of the source cavity 109. The source cavity 109 may be expanded in volume by removal of the portions of the memory films 50 at the level of the source cavity 109 and the upper and lower sacrificial liners. A top surface of the lower source-level semiconductor layer 112 and a bottom surface of the upper source-level semiconductor layer 116 may be physically exposed to the source cavity 109. The source cavity 109 is formed by isotropically etching the source-level sacrificial layer 104 and a bottom portion of each of the memory films 50 selective to at least one source-level semiconductor layer (such as the lower source-level semiconductor layer 112 and the upper source-level semiconductor layer 116) and the vertical semiconductor channels 60.

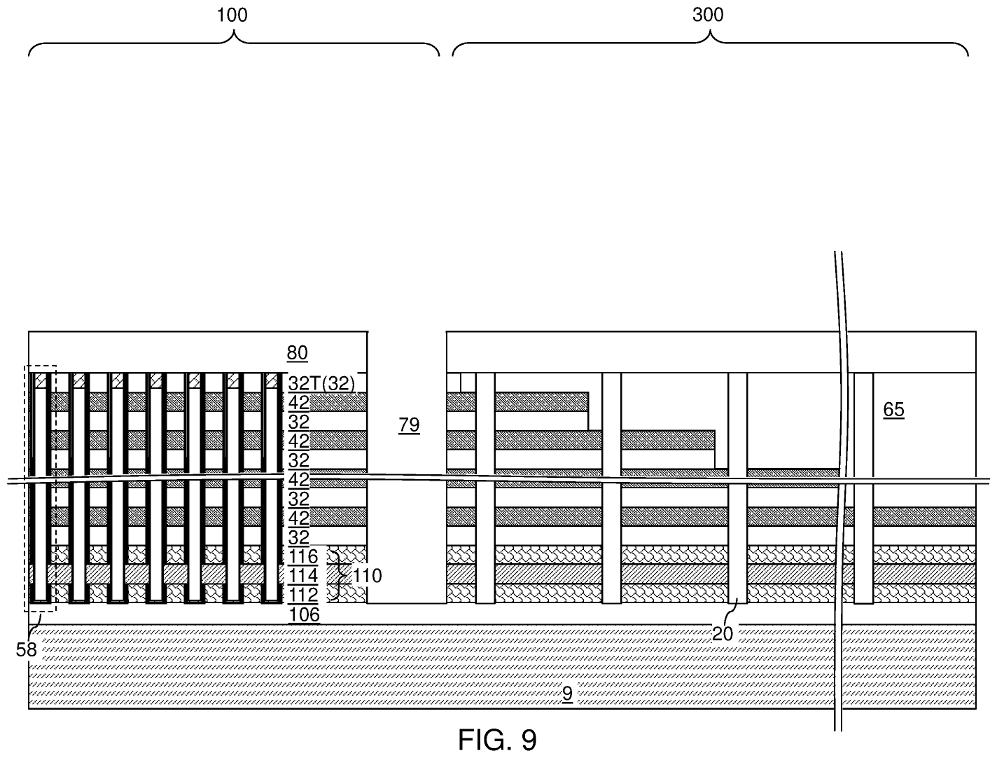

Referring to FIG. 9, a semiconductor material having a doping of the second conductivity type may be deposited on the physically exposed semiconductor surfaces around the source cavity 109. The physically exposed semiconductor surfaces include bottom portions of outer sidewalls of the vertical semiconductor channels 60 and a horizontal surface of the at least one source-level semiconductor layer (such as a bottom surface of the upper source-level semiconductor layer 116 and/or a top surface of the lower source-level semiconductor layer 112). For example, the physically exposed semiconductor surfaces may include the bottom portions of outer sidewalls of the vertical semiconductor channels 60, the top horizontal surface of the lower source-level semiconductor layer 112, and the bottom surface of the upper source-level semiconductor layer 116.

In one embodiment, the doped semiconductor material of the second conductivity type may be deposited on the physically exposed semiconductor surfaces around the source cavity 109 by a selective semiconductor deposition process. A semiconductor precursor gas, an etchant, and a dopant gas may be flowed concurrently into a process chamber including the exemplary structure during the selective semiconductor deposition process. For example, the semiconductor precursor gas may include silane, disilane, or dichlorosilane, the etchant gas may include gaseous hydrogen chloride, and the dopant gas may include a hydride of a dopant atom such as phosphine, arsine, stibine, or diborane. In this case, the selective semiconductor deposition process grows a doped semiconductor material having a doping of the second conductivity type from physically exposed semiconductor surfaces around the source cavity 109. The deposited doped semiconductor material forms a source contact layer 114, which may contact sidewalls of the vertical semiconductor channels 60. The atomic concentration of the dopants of the second conductivity type in the deposited semiconductor material may be in a range from 1.0×10²⁰/cm³ to 2.0×10²¹/cm³, such as from 2.0×10²⁰/cm³ to 8.0×10²⁰/cm³. The source contact layer 114 as initially formed may consist essentially of semiconductor atoms and dopant atoms of the second conductivity type. Alternatively, at least one non-selective doped semiconductor material deposition process may be used to form the source contact layer 114. Optionally, one or more etch back processes may be used in combination with a plurality of selective or non-selective deposition processes to provide a seamless and/or voidless source contact layer 114.

The duration of the selective semiconductor deposition process may be selected such that the source cavity 109 is filled with the source contact layer 114. In one embodiment, the source contact layer 114 may be formed by selectively depositing a doped semiconductor material having a doping of the second conductivity type from semiconductor surfaces around the source cavity 109. In one embodiment, the doped semiconductor material may include doped polysilicon. Thus, the source-level sacrificial layer 104 may be replaced with the source contact layer 114. The layer stack including the lower source-level semiconductor layer 112, the source contact layer 114, and the upper source-level semiconductor layer 116 constitutes a source layer 110, which replaces the in-process source-level material layers 110′. The source layer 110 contacts an end portion of each of the vertical semiconductor channels 60.

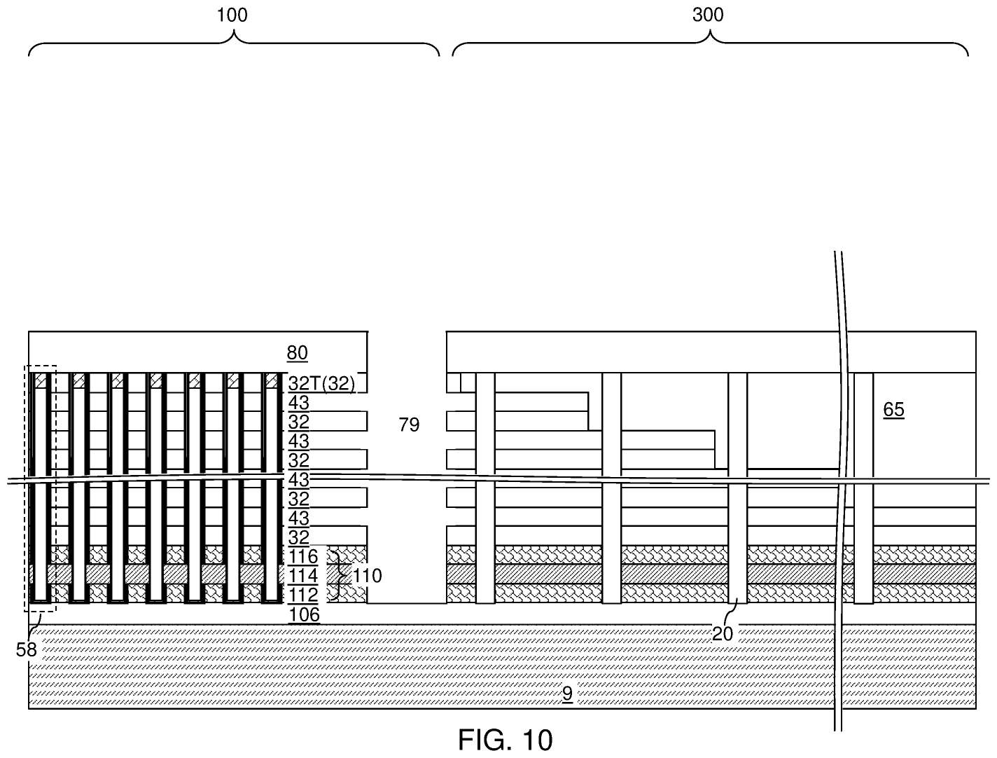

Referring to FIG. 10, an isotropic etch process can be performed to remove the sacrificial material layers 42 selective to the insulating layers 32, the stopper insulating layer 106, the memory opening fill structures 58, the sacrificial etch stop liners 71, and the source layer 110. Laterally-extending cavities 43 can be formed in volumes from which the sacrificial material layers 42 are removed. Sidewall surface segments of the memory opening fill structures 58 can be physically exposed to the laterally-extending cavities 43. In an illustrative example, if the sacrificial material layers 42 comprise silicon oxide, the isotropic etch process may comprise a wet etch process employing hot phosphoric acid, which is a process in which the exemplary structure is immersed in phosphoric acid at, or near, the boiling point of the phosphoric acid. A suitable clean process may be performed as needed.

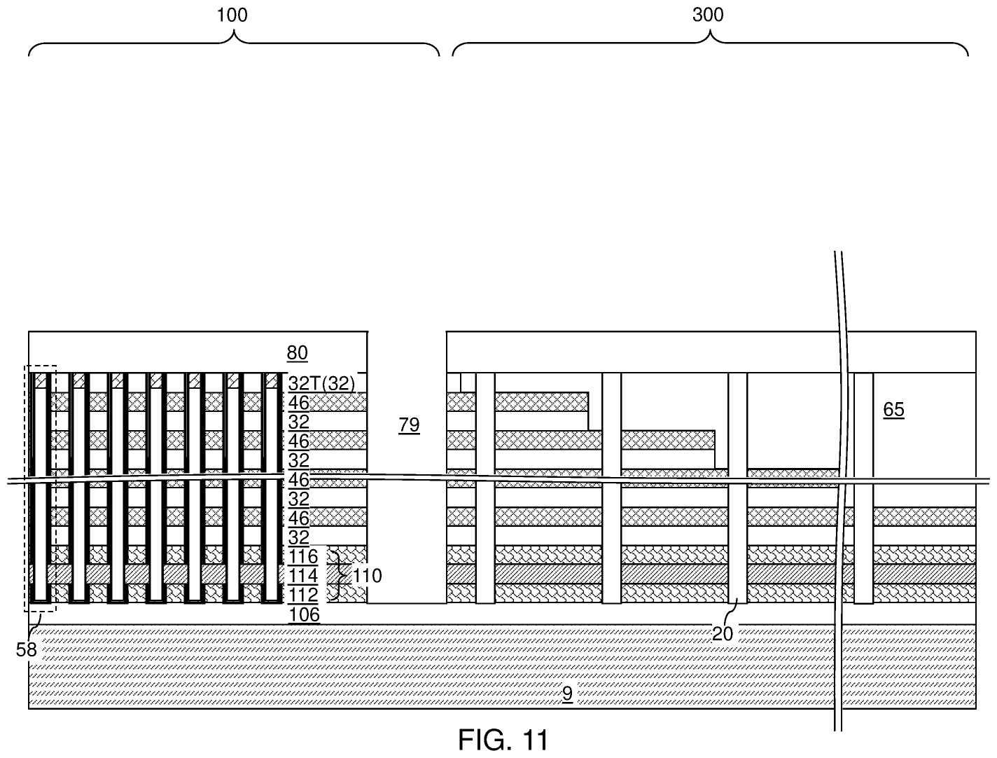

Referring to FIG. 11, a backside blocking dielectric layer (not shown) can be optionally formed in the laterally-extending cavities 43 by a conformal deposition process. At least one conductive material, such as at least one metallic material, can be conformally deposited in the laterally-extending cavities 43. At least one chemical vapor deposition process and/or at least one atomic layer deposition process can be employed to deposit the at least one conductive material.

The at least one conductive material may comprise, for example, a combination of a metallic barrier material and a metallic fill material. The metallic barrier material may comprise, for example, TiN, TaN, WN, MON, TiC, TaC, WC, or a combination thereof. The metallic fill material may comprise, for example, Ti, Ta, Mo, Co, Ru, W, Cu, other transition metals, and/or alloys or layer stacks thereof. Excess portions of the at least one conductive material that are deposited in the lateral isolation trenches 79 or above the contact-level dielectric layer 80 can be removed by performing an etch-back process, which may comprise an isotropic etch process and/or an anisotropic etch process. Each remaining portion of the at least one conductive material filling a respective one of the laterally-extending cavities 43 constitutes an electrically conductive layer 46. An alternating stack of insulating layers 32 and electrically conductive layers 46 can be formed between each neighboring pair of lateral isolation trenches 79 over the carrier substrate 9. A plurality of alternating stacks of insulating layers 32 and electrically conductive layers 46 can be laterally spaced apart among one another by the lateral isolation trenches 79.

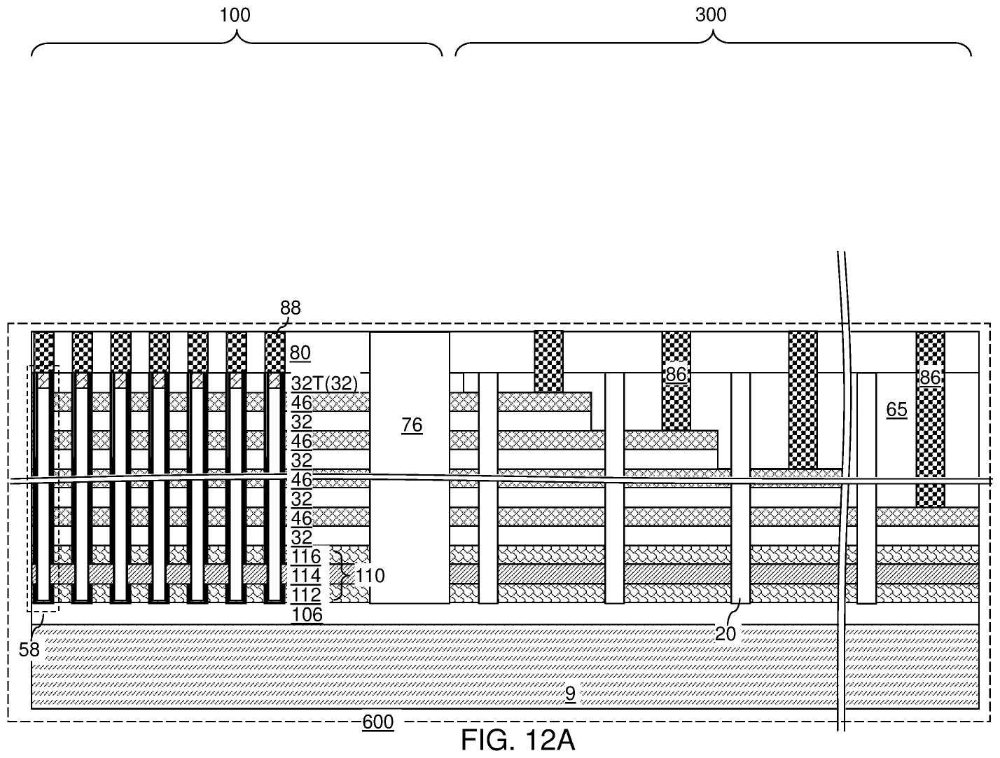

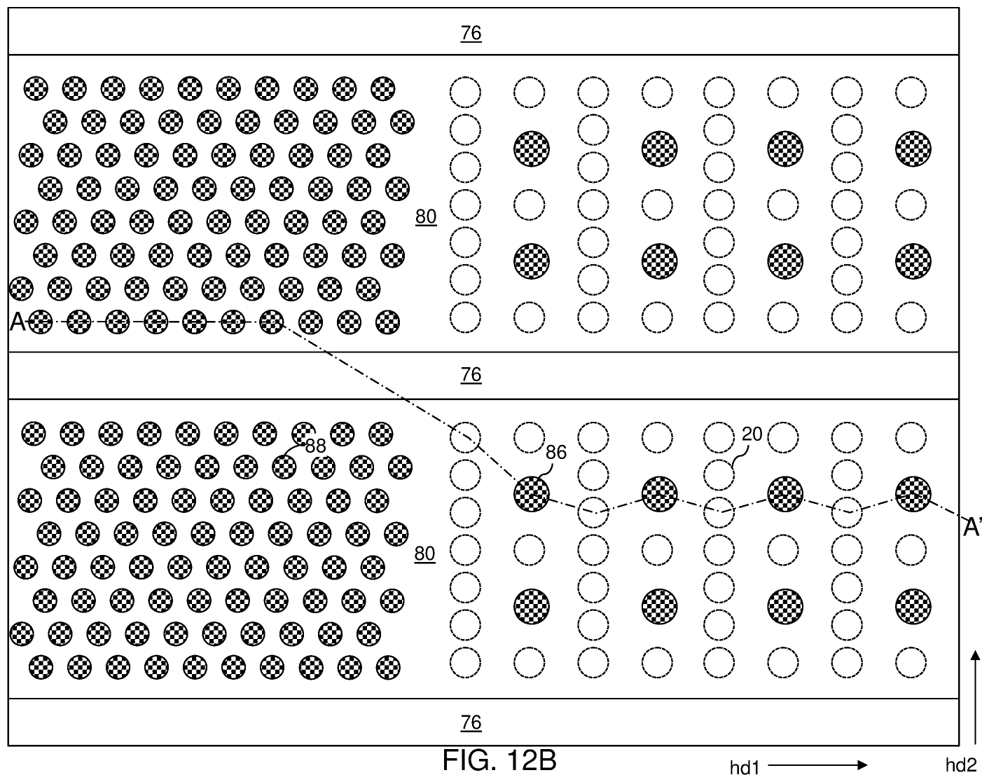

Referring to FIGS. 12A and 12B, an insulating fill material may be conformally deposited in the lateral isolation trenches 79. Excess portions of the insulating fill material may be removed from above the contact-level dielectric layer 80, for example, by a recess etch process. Each remaining portion of the insulating fill material that fills a respective lateral isolation trench 79 constitutes an isolation trench fill structure 76. Alternatively, each isolation trench fill structure 76 may comprise a combination of a tubular insulating spacer (not expressly shown) and a conductive connection via structure (not expressly shown) that is laterally surrounded by the tubular insulating spacer.

A photoresist layer (not shown) can be applied over the contact-level dielectric layer 80, and can be lithographically patterned to form openings over each of the memory opening fill structures 58 over the horizontally-extending surfaces of the stepped surfaces in the contact region. An anisotropic etch process can be performed to transfer the pattern of the openings in the photoresist layer through the contact-level dielectric layer 80 and the retro-stepped dielectric material portion 65. Drain contact via cavities can be formed through the contact-level dielectric layer 80 over the memory opening fill structures 58. Layer contact via structures can be formed through the contact-level dielectric layer 80 and the retro-stepped dielectric material portion 65 on a top surface of a respective one of the electrically conductive layers 46. The photoresist layer can be subsequently removed, for example, by ashing.

At least one conductive material, such as a combination of a metallic barrier material and a metallic fill material, can be deposited in the drain contact via cavities and the layer contact via cavities. Excess portions of the at least one conductive material can be removed from above the horizontal plane including the top surface of the contact-level dielectric layer 80 by a planarization process, which may employ a recess etch process and/or a chemical mechanical polishing process. Remaining portions of the at least one conductive material that fill the drain contact via cavities constitute drain contact via structures 88 contacting a top surface of a respective one of the drain regions 63. Remaining portions of the at least one conductive material that fill the layer contact via cavities constitute layer contact via structures 86 contacting a top surface of a respective one of the electrically conductive layers 46.

Generally, a three-dimensional memory device 600 is formed, which comprises an alternating stack (32, 46) of insulating layers 32 and electrically conductive layers 46 that alternate along a vertical direction, memory openings 49 vertically extending through the alternating stack (32, 46), and memory opening fill structures 58 located in the two-dimensional array of memory openings 49. Each of the memory opening fill structures 58 comprises a respective vertical stack of memory elements (e.g., portions of the memory film 50) located at levels of the electrically conductive layers 46 and a vertical semiconductor channel 60. The memory opening fill structures 58 may comprise vertical NAND strings and the electrically conductive layers 46 comprise word lines and select gate electrodes for the vertical NAND strings.

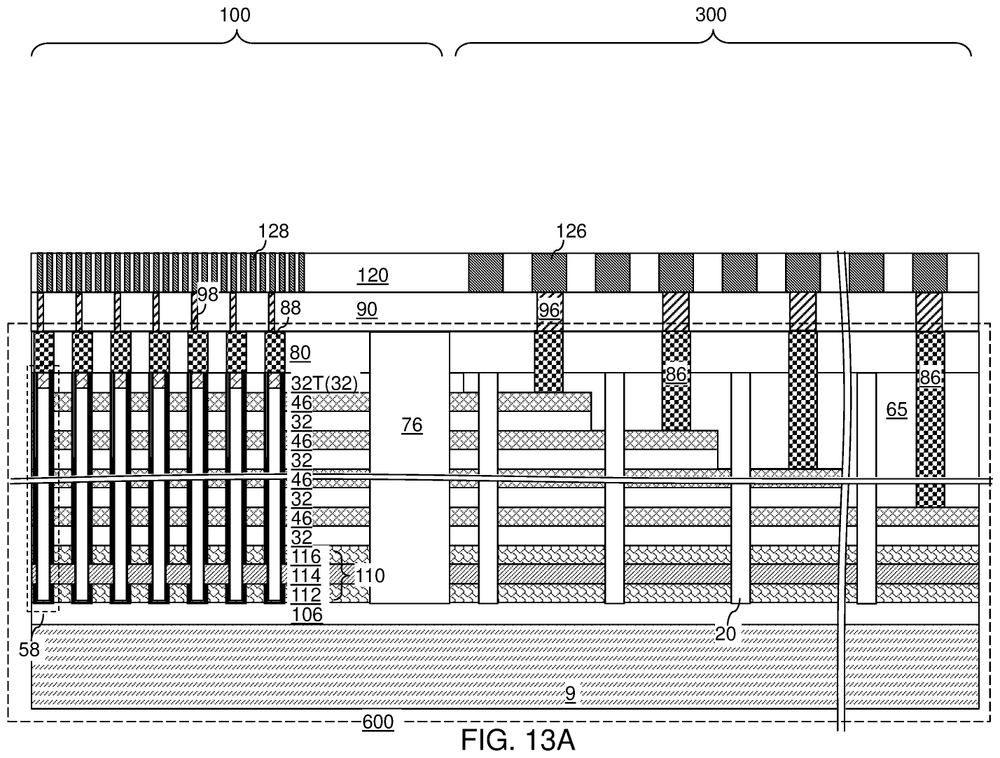

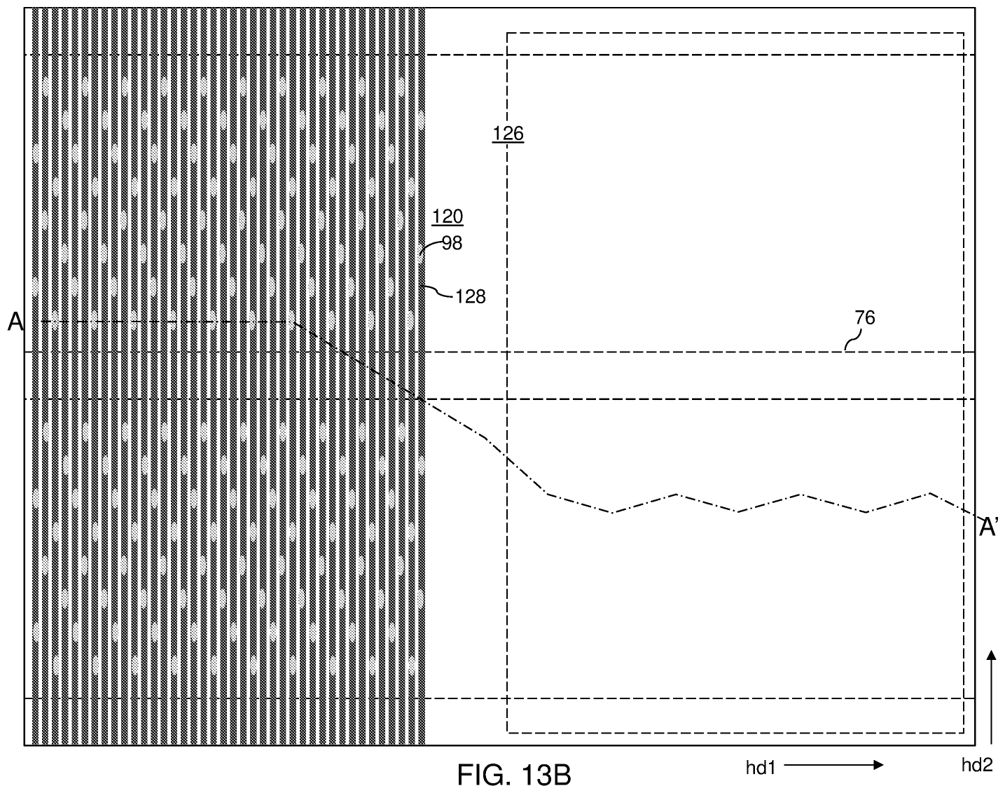

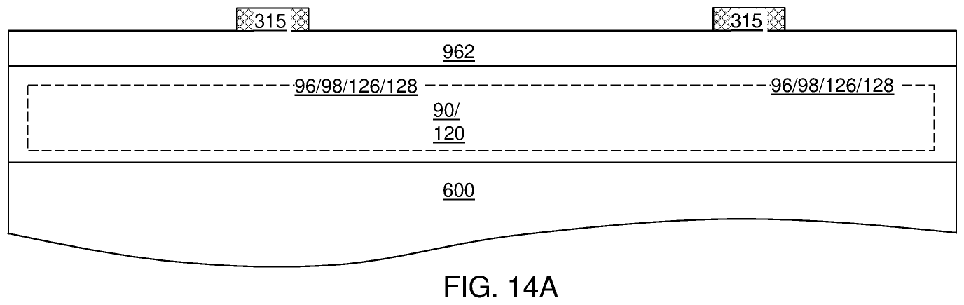

Referring to FIGS. 13A and 13B, first metal interconnect structures (98, 96, 128, 126) including connection-level via structures (98, 96) and bit-line-level metal lines (128, 126) can be formed over the contact-level dielectric layer 80. For example, a connection-level dielectric layer 90 can be formed above the contact-level dielectric layer 80. Connection via cavities can be formed through the connection-level dielectric layer 90, and can be filled with at least one conductive material (which may comprise at least one metallic material) to form the connection-level via structures (98, 96). The connection-level via structures (98, 96) comprise drain connection via structures 98 that contact a respective one of the drain contact via structures 88, and layer connection via structures 96 that contact a respective one of the layer contact via structures 86.

A bit-line-level dielectric layer 120 can be formed above the connection-level dielectric layer 90. Bit-line-level line cavities can be formed through the bit-line-level dielectric layer 120, and can be filled with at least one conductive material (which may comprise at least one metallic material) to form bit-line-level metal lines (128, 126). The bit-line-level metal lines may comprise bit lines 128 that laterally extend generally along the second horizontal direction hd2 with periodic change of lateral extension directions such that the periodicity of the periodic change of the lateral extension directions is the same as the periodicity of the isolation trench fill structures 76. This feature can occur when the first lateral offset distance D is not equal to zero, as in the case of the first through fourth configurations of the arrays of memory openings 49 (and thus, of the arrays of memory opening fill structures 58) described above. In this case, the tilt angle of longer sections of the bit lines 128 relative to the second horizontal direction hd2 may be the arctangent of the ratio of the first lateral offset distance D to the center-to-center distance between neighboring pairs of even-numbered rows of memory openings 49 (which is the same as the center-to-center distance between neighboring pairs of even-numbered rows of memory opening fill structures 58).

Generally, each of the memory opening fill structures 58 comprises a respective vertical semiconductor channel 60 and a respective drain region 63 contacting an end portion of the respective vertical semiconductor channel 60. The first metal interconnect structures (98, 96, 128, 126) comprise bit lines 128 extending along the second horizontal direction (e.g., bit line direction hd2), laterally spaced apart from each other along a first horizontal direction (e.g., word line direction) hd1 and electrically connected to a respective subset of the drain regions 63. The first metal interconnect structures (98, 96, 128, 126) are embedded within first dielectric material layers (90, 120) that overlie the three-dimensional memory device 600, and are electrically connected to a respective node (e.g., respective drain regions 63 and electrically conductive layers 46) within the three-dimensional memory device 600.

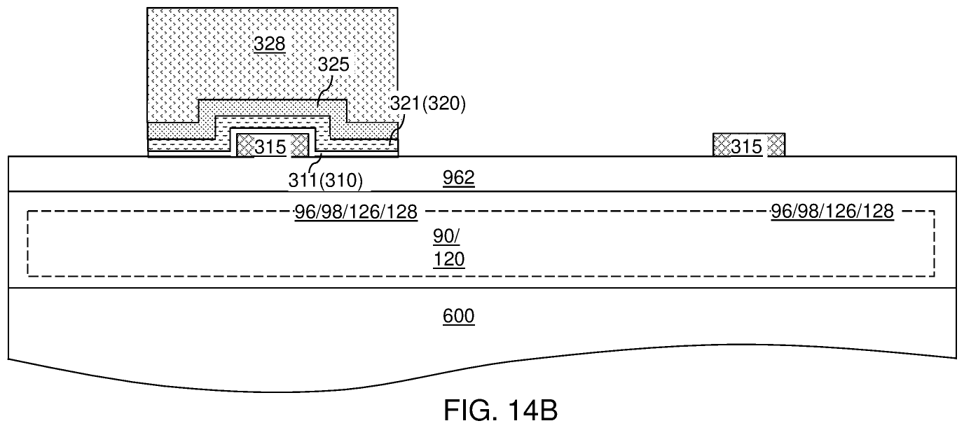

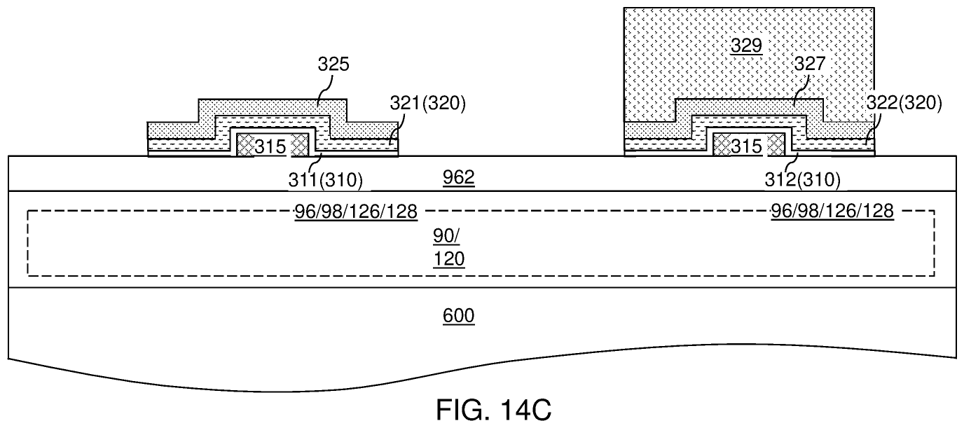

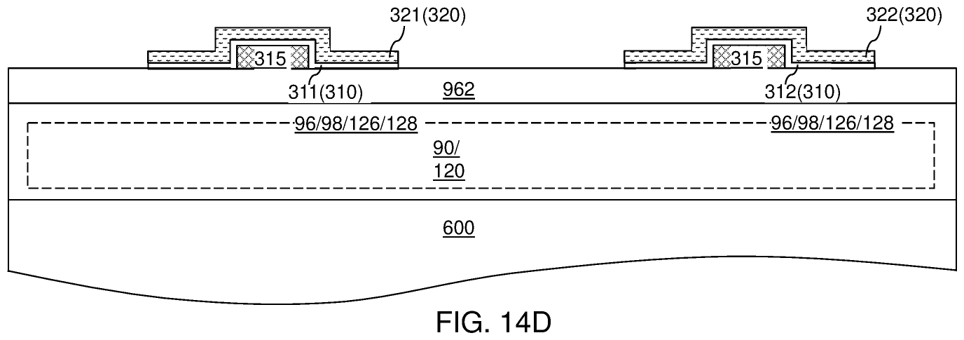

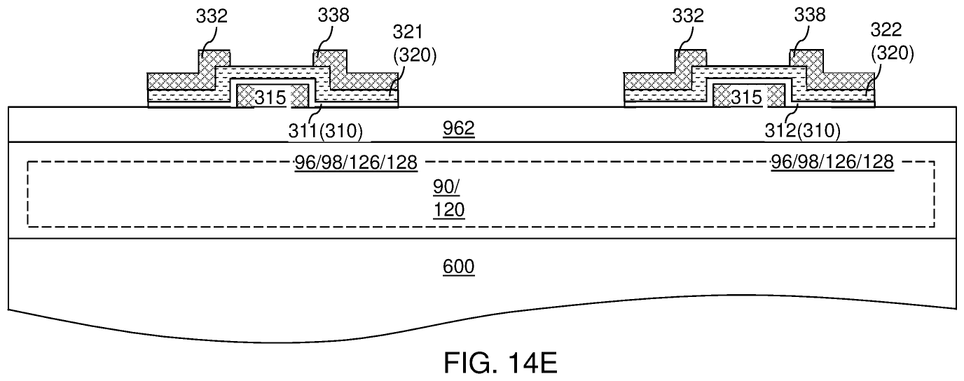

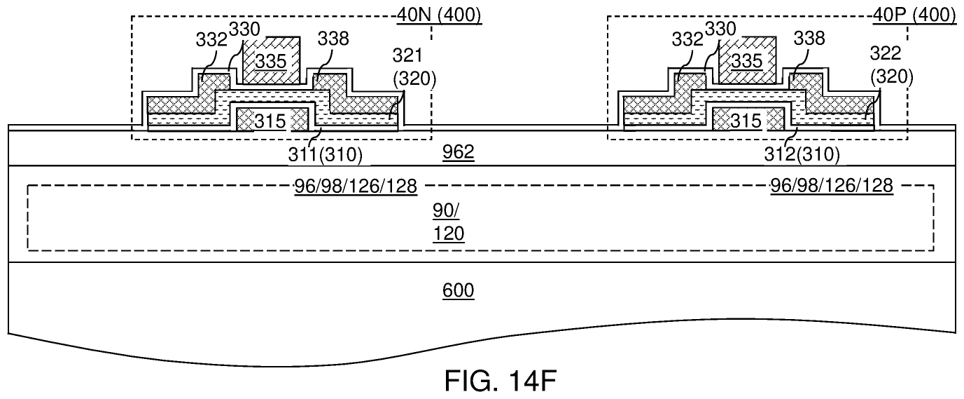

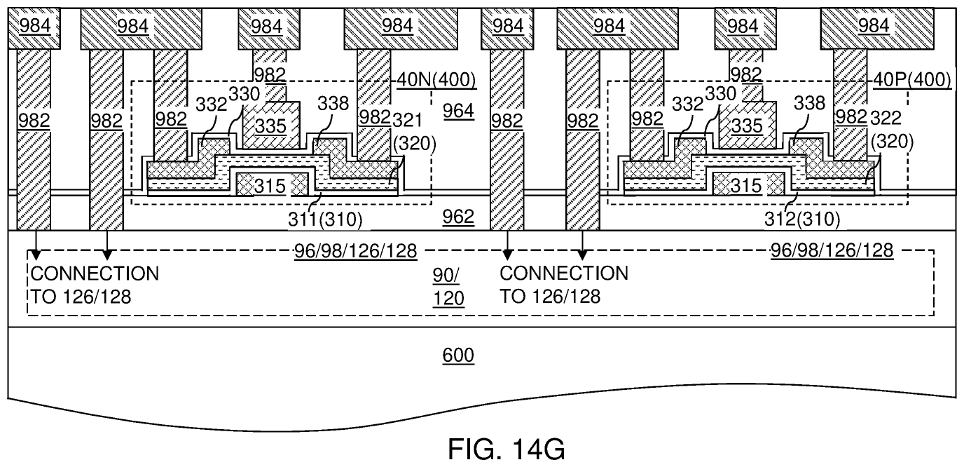

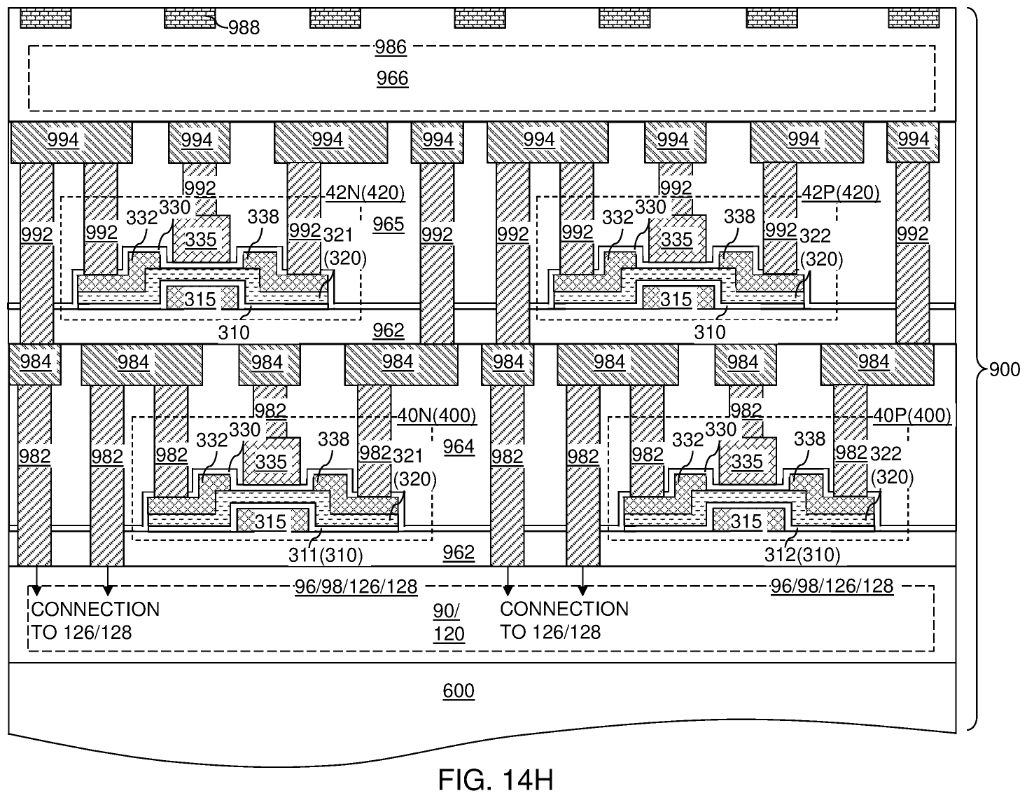

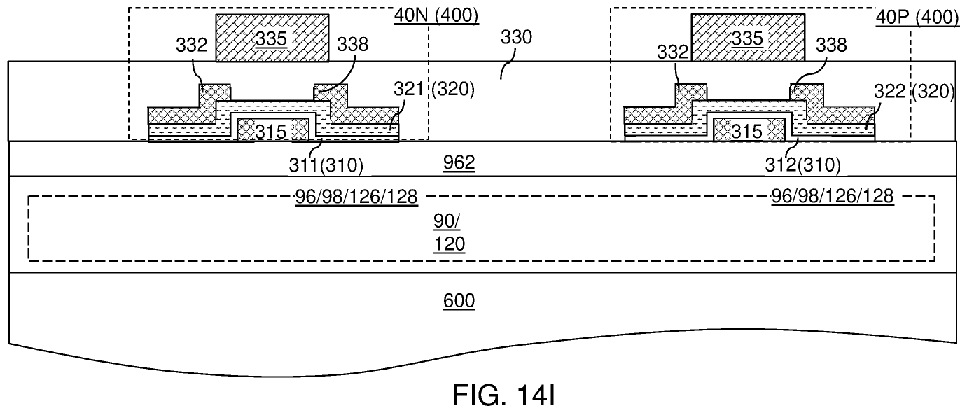

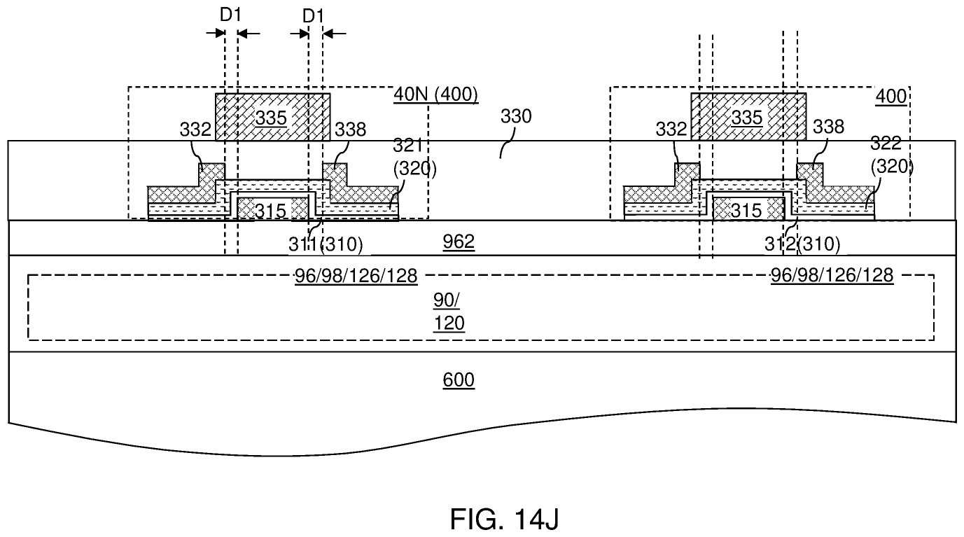

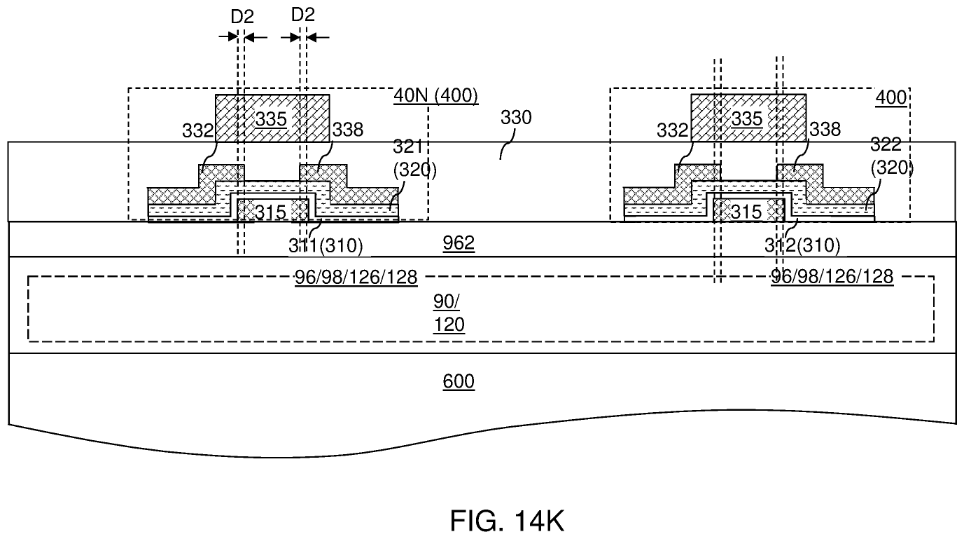

According to an aspect of the present disclosure, thin film transistors are subsequently formed over the three-dimensional memory device 600. FIGS. 14A-14H are sequential vertical cross-sectional view of an upper portion of the exemplary structure during formation of a first planar dielectric spacer layer 962, first thin film transistors 400, second metal interconnect structures (982, 984), optional second thin film transistors 420, third metal interconnect structures (992, 994), memory-side dielectric material layers 966 and memory-side metal interconnect structures 986, and memory-side bonding pads 988 according to an embodiment of the present disclosure.

Referring to FIG. 14A, a planar dielectric spacer layer 962 (also referred to as a first planar dielectric spacer layer) comprising a dielectric material, such as silicon oxide or organosilicate glass, can be formed over the first dielectric material layers (90, 120). The thickness of the planar dielectric spacer layer 962 may be in a range from 20 nm to 300 nm, although lesser and greater thicknesses may also be employed. The planar dielectric spacer layer 962 provides electrical isolation between the first metal interconnect structures (98, 96, 128, 126) and first thin film transistors to be subsequently formed.

A conductive material layer can be deposited over the planar dielectric spacer layer 962, and can be patterned to form first bottom gate electrodes 315. The first bottom gate electrodes 315 may comprise any bottom gate electrode material that can be employed for thin film transistors. For example, the first bottom gate electrodes may comprise Al, Mo, heavily doped polysilicon or a stack of Ti/TiN/W layers. A passivation material may optionally be formed on the first bottom gate electrodes 315.

Referring to FIG. 14B, a first-type bottom gate dielectric layer used to form a first-type bottom gate dielectric 311, a first-type semiconductor material layer used to form first semiconductor channels 321, and an optional first hard mask layer 325 can be deposited over the first bottom gate electrodes 315 and the planar dielectric spacer layer 962. The first-type bottom gate dielectric layer comprises a first bottom gate dielectric material that is suitable as a bottom gate dielectric material for first-type thin film transistors to be subsequently formed, and the first-type semiconductor material layer comprises a first semiconductor material that is suitable as a channel material for the first-type thin film transistors to be subsequently formed. In an illustrative example, the first-type bottom gate dielectric layer may comprise silicon oxide or a dielectric metal oxide material (e.g., hafnium oxide or aluminum oxide), and may have a thickness in a range from 5 nm to 40 nm, although lesser and greater thicknesses may also be employed. In one embodiment, the first hard mask layer 325 may comprise silicon nitride or a metal.

The first-type semiconductor material layer comprises a first non-single-crystalline semiconductor material, which may be amorphous or polycrystalline. The first-type semiconductor material layer may be deposited at a temperature below 400 degrees Celsius, such as 25 to 350 degrees Celsius, to avoid negatively impacting the performance of the underlying memory device 600. In one embodiment, the first non-single-crystalline semiconductor material may comprise a semiconductor metal oxide material, an organic metal halide perovskite semiconductor material, or a two-dimensional semiconductor material exhibiting higher in-plane electrical conductivity than out-of-plane conductivity.

For example, if the first non-single-crystalline semiconductor material is used for a channel of a lower speed n-type thin film transistor (TFT), then the first non-single-crystalline semiconductor material may comprise a metal oxide material, such as indium gallium zinc oxide (IGZO), indium tin zinc oxide, indium zinc oxide, hafnium indium zinc oxide, zirconium indium zinc oxide, zirconium indium tin oxide, or zinc indium tin oxide. Alternatively, if the first non-single-crystalline semiconductor material is used for a channel of a lower speed p-type thin film transistor (TFT), then the first non-single-crystalline semiconductor material may comprise the organic metal halide perovskite semiconductor material, such as an organic tin iodide, for example FASnI₃ (where FA comprises CN₂H₅ or another organic molecule), and/or PEA₂SnI₄ (where PEA comprises phenethylamine). If the first non-single-crystalline semiconductor material is used for a channel of a higher speed TFT, then the first non-single-crystalline semiconductor material may comprise the two-dimensional semiconductor material, such as MoS₂ for a n-type TFT or WS₂ for a p-type TFT.

A first photoresist layer 328 can be applied over the first hard mask layer 325, and can be lithographically patterned to cover areas of the first semiconductor channels 321 to be subsequently patterned out of the first-type semiconductor material layer. At least one anisotropic etch process can be performed transfer the pattern in first photoresist layer 328 through the first hard mask layer 325, the first-type semiconductor material layer, and the first-type bottom gate dielectric layer. Each patterned portion of the first-type semiconductor material layer comprises a first-type semiconductor channel 321, which is a first semiconductor channel 320 of a first type. Each patterned portion of the first-type bottom gate dielectric layer comprises the first-type bottom gate dielectric 311, which is a first bottom gate dielectric of a first type. The materials of the first semiconductor material of the first-type semiconductor channel 321 and the first bottom gate dielectric material of the first-type bottom gate dielectric 311 may be optimized for a thin film transistor of a first type, which may be p-type or n-type, as described above. The first photoresist layer 328 can be subsequently removed, for example, by ashing.

Referring to FIG. 14C, a second-type bottom gate dielectric layer used to form a second-type bottom gate dielectric 312, a second-type semiconductor material layer used to form a second-type semiconductor channel 322, and a second hard mask layer 327 can be deposited. The first-type semiconductor material layer may be deposited at a temperature below 400 degrees Celsius, such as 25 to 350 degrees Celsius, to avoid negatively impacting the performance of the underlying memory device 600. The second-type bottom gate dielectric layer comprises a second bottom gate dielectric material that is suitable as a bottom gate dielectric material for second-type thin film transistors to be subsequently formed, and the second-type semiconductor material layer comprises a second semiconductor material that is suitable as a channel material for the second-type thin film transistors to be subsequently formed. In an illustrative example, the second-type bottom gate dielectric layer may comprise silicon oxide or a dielectric metal oxide material, and may have a thickness in a range from 5 nm to 40 nm, although lesser and greater thicknesses may also be employed. In one embodiment, the second hard mask layer 327 may comprise silicon nitride or a metal, and may be thinner than the first hard mask layer 325.

The second-type semiconductor material layer comprises a second non-single-crystalline semiconductor material, which may be amorphous or polycrystalline. In one embodiment, the second non-single-crystalline semiconductor material may comprise the semiconductor metal oxide material, the organic metal halide perovskite semiconductor material, such as the organic tin iodide, or the two-dimensional semiconductor material exhibiting higher in-plane electrical conductivity than out-of-plane conductivity. For example, the second non-single-crystalline semiconductor material may comprise a material selected from the list of semiconductor materials discussed above. If the first non-single-crystalline semiconductor material comprises an n-type semiconductor material, then the second non-single-crystalline semiconductor material comprises a p-type material or vice-versa.

A second photoresist layer 329 can be applied over the second hard mask layer 327, and can be lithographically patterned to cover areas of second semiconductor channels 322 to be subsequently patterned out of the second-type semiconductor material layer. At least one anisotropic etch process can be performed transfer the pattern in second photoresist layer 329 through the second hard mask layer 327, the second-type semiconductor material layer, and the second-type bottom gate dielectric layer. Each patterned portion of the second-type semiconductor material layer comprises the second-type semiconductor channel 322, which is a first semiconductor channel 320 of a second type. Each patterned portion of the second-type bottom gate dielectric layer comprises the second-type bottom gate dielectric 311, which is a first bottom gate dielectric 310 of a second type. The second semiconductor material of the second-type semiconductor channel 322 and the second bottom gate dielectric material of the second-type bottom gate dielectric 312 may be selected for a thin film transistor of a second type, which may be n-type of p-type, and is preferably of the opposite conductivity type to that of the thin film transistor of the first type. The second photoresist layer 329 can be subsequently removed, for example, by ashing.

In one embodiment, the thin film transistors of the first type may be n-type thin film transistors (in which the minority charge carriers are n-type carriers) and the thin film transistors of the second type may be p-type thin film transistors (in which the minority charge carriers are p-type carriers), or vice versa. Alternatively or additionally, the thin film transistors of the first type may employ a first semiconductor material providing a low leakage current and the thin film transistors of the second type may employ a second semiconductor material providing high electron mobility, or vice versa. Generally, multiple semiconductor materials optionally having different thicknesses may be employed to provide multiple types of semiconductor channel materials for multiple types of thin film transistors.

Referring to FIG. 14D, the first hard mask layer 325 and the second hard mask layer 327 can be removed selective to the first semiconductor channels 320 by performing a selective etch process, which may comprise a wet etch process and/or a reactive ion etch process. The hard mask layers (325, 327) are used to protect the first semiconductor channels 320 from etch damage during the previous patterning steps.

Referring to FIG. 14E, an electrically conductive material can be deposited over the first semiconductor channels 320, and can be patterned employing a combination of photolithography and etching (such as an anisotropic etch process) to form pairs of a first source electrode 332 and a first drain electrode 338. The electrically conductive material may comprise a metal, such as Al, Mo, Cu or Au. A passivation material may optionally be formed under the electrically conductive material.

Referring to FIG. 14F, an optional first top gate dielectric 330 can be formed over the physically exposed top surfaces of the first semiconductor channels 320, the first source electrodes 332, and the first drain electrodes 338. An optional electrically conductive gate electrode material layer can be deposited over the first top gate dielectric 330, and can be patterned to form optional first top gate electrodes 335 overlying a respective one of the first semiconductor channels 320. The first top gate electrodes 335 may comprise the same material as the first bottom gate electrodes 315. First dual gated thin film transistors 400 are formed over the planar dielectric spacer layer 962. Alternatively, the top gate electrodes 335 may be omitted to form bottom gated thin film transistors 400, or the bottom gate electrodes 315 may be omitted to form top gated thin film transistors 400.

The first thin film transistors 400 are located over the first dielectric material layers (90, 120). In this case, the planar dielectric spacer layer 962 can be interposed between the first dielectric material layers (90, 120) and first thin film transistors 400. In one embodiment, each of the first thin film transistors 400 comprises a respective first gate dielectric (such as a first bottom gate dielectric 310) having a respective planar bottom surface that contacts a respective segment of a horizontal surface of the planar dielectric spacer layer 962.

In one embodiment, each of the first thin film transistors 400 comprises a respective first bottom gate electrode 315 contacting the planar dielectric spacer layer 962; a respective first semiconductor channel 320 that overlies the respective first gate dielectric 310; a respective first source electrode 332 contacting a first end portion of the respective first semiconductor channel 320; and a respective first drain electrode 338 contacting a second end portion of the respective first semiconductor channel 320.

In one embodiment, a first subset of the first thin film transistors 400 comprises a respective semiconductor channel 320 including a first semiconductor channel material having a first conductivity (e.g., n-type), and a second subset of the first thin film transistors 400 comprises a respective semiconductor channel 320 including a second semiconductor channel material having a second conductivity (e.g., p-type) In one embodiment, a first subset of the first thin film transistors 400 comprises n-type thin film transistors 40N and a second subset of the first thin film transistors 400 comprises p-type thin film transistors 40P.

Referring to FIG. 14G, second metal interconnect structures (982, 984) embedded within second dielectric material layers 964 can be formed over the first thin film transistors 400. The second metal interconnect structures (982, 984) may comprise metal via structures 982 and metal lines 984. A subset of the second metal interconnect structures (982, 984) can directly contact, and/or can be electrically connected to, the bit-line-level metal lines (128, 126).

In one embodiment, the subset of the second metal interconnect structures (982, 984) provides electrical connection between a respective one of the first thin film transistors 400 and a respective electrical node of the three-dimensional memory device 600. Another subset of the second metal interconnect structures (982, 984) may provide electrical connection among the first thin film transistors 400.

In one embodiment, the first thin film transistors 400 and the second metal interconnect structures (982, 984) may be interconnected among one another to provide a control circuit, such as a word line control circuit (e.g., word line switching circuit and/or word line decoder circuit) that controls operation of the three-dimensional memory device 600, such as the operation of the word lines of the three-dimensional memory device 600. In one embodiment, the first thin film transistors 400 can be formed over the first dielectric material layers (90, 120), and can be electrically connected to a respective electrical node (e.g., the electrically conductive layers 46 which function as word lines) within the three-dimensional memory device 600 through a respective subset of the first metal interconnect structures (96, 126). In one embodiment, a subset of the first thin film transistors 400 comprises high voltage devices, such as word line switches each electrically connecting or disconnecting a respective one of the electrically conductive layers 46. In another embodiment, a subset of the first thin film transistors 400 may comprise sense amplifiers that are electrically connected to a respective one of the bit lines 128.

In one embodiment, a first subset of the first thin film transistors 400 comprises n-type thin film transistors 40N; a second subset of the first thin film transistors 400 comprises p-type thin film transistors 40P; the second metal interconnect structures (982, 984) are embedded within the second dielectric material layers 964 (which overlie the first thin film transistors 400) and provide electrical connection among the first thin film transistors 400. The first thin film transistors 400 and the second metal interconnect structures (982, 984) are interconnected among one another to provide a control circuit that controls operation of the three-dimensional memory device 600. In this case, the control circuit includes the first thin film transistors 400 comprises a complementary metal-oxide-semiconductor (CMOS) circuit.

Referring to FIG. 14H, another planar dielectric spacer layer 962 (also referred to as a second planar dielectric spacer layer) comprising a dielectric material, such as silicon oxide or organosilicate glass can be formed over the second dielectric material layers 962. The processing steps described with reference to FIGS. 14A-14G can optionally be repeated with any needed changes to form second thin film transistors 420, third dielectric material layers 965, and third metal interconnect structures (992, 994) over the first thin film transistors 420.

The third metal interconnect structures (992, 994) can be embedded within the third dielectric material layers 965. The third metal interconnect structures (992, 994) may comprise metal via structures 992 and metal lines 994. A subset of the third metal interconnect structures (992, 994) can directly contact a subset the second metal interconnect structures (982, 984). The subset of the third metal interconnect structures (992, 994) can be electrically connected to the subset the second metal interconnect structures (982, 984) and to the bit-line-level metal lines (128, 126). In one embodiment, the subset of the third metal interconnect structures (992, 994) provides electrical connection between a respective one of the second thin film transistors 420 and a respective electrical node of the three-dimensional memory device 600. Another subset of the third metal interconnect structures (992, 994) may provide electrical connection among the second thin film transistors 420.

In one embodiment, the second thin film transistors 420 and the third metal interconnect structures (992, 994) may be interconnected among one another to provide a control circuit that controls operation of the three-dimensional memory device 600. In one embodiment, the second thin film transistors 420 can be formed over the second dielectric material layers 964, and can be electrically connected to a respective electrical node within the three-dimensional memory device 600 through a respective subset of the second metal interconnect structures (982, 984) and through a respective subset of the first metal interconnect structures (98, 96, 128, 126). In one embodiment, a subset of the second thin film transistors 420 comprises high voltage devices, such as word line switches each electrically connecting or disconnecting a respective one of the electrically conductive layers 46. In another embodiment, a subset of the second thin film transistors 420 comprises sense amplifiers each electrically connected to a respective one of the bit lines 128.

In one embodiment, a first subset of the second thin film transistors 420 comprises n-type thin film transistors 42N; a second subset of the second thin film transistors 420 comprises p-type thin film transistors 42P; the third metal interconnect structures (992, 994) are embedded within the third dielectric material layers 964 (which overlie the second thin film transistors 420) and provide electrical connection among the second thin film transistors 420; and the second thin film transistors 420 and the third metal interconnect structures (992, 994) are interconnected among one another to provide a control circuit that controls operation of the three-dimensional memory device 600. In this case, the control circuit includes the second thin film transistors 420 and comprises a complementary metal-oxide-semiconductor (CMOS) circuit. Alternatively, the second thin film transistors 420 and the third metal interconnect structures (992, 994) may be omitted.

Additional dielectric material layers and additional metal interconnect structures can be formed over the third dielectric material layers 965. The additional dielectric material layers may include at least one via-level dielectric layer, at least one additional line-level dielectric layer, and/or at least one additional line-and-via-level dielectric layer. The additional metal interconnect structures may comprise metal via structures, metal line structures, and/or integrated metal line-and-via structures. The additional dielectric material layers that are formed above the third dielectric material layers 965 are herein referred to as memory-side dielectric material layers 966. The additional metal interconnect structures are collectively referred to as memory-side metal interconnect structures 986.

Metal bonding pads, which are herein referred to as memory-side bonding pads 988, may be formed at the topmost level of the memory-side dielectric material layers 966. The memory-side bonding pads 988 may be electrically connected to the memory-side metal interconnect structures 986 and various nodes of the three-dimensional memory device 600 including the alternating stacks of insulating layers 32 and electrically conductive layers 46 and the memory opening fill structures 58. A memory die 900 can thus be provided.

Generally, the memory-side metal interconnect structures 986 can be embedded within memory-side dielectric material layers 966 that overlie the first thin film transistors 400 and the optional second thin film transistors 420. A first subset of the memory-side metal interconnect structures 986 may be electrically connected to a respective one of the first thin film transistors 400, and a second subset of the memory-side metal interconnect structures 986 may be electrically connected to a respective one of the second thin film transistors 420. The memory-side bonding pads 988 can be embedded in an upper portion of the memory-side dielectric material layers 966, and can be electrically connected to the memory-side metal interconnect structures 986. The exemplary structure comprises a memory die 900 including memory-side bonding pads 988.

Referring to FIG. 14I, an alternative configuration of the exemplary structure is illustrated, which can be derived from the exemplary structure illustrated in FIG. 14F by increasing the thickness of the first top gate dielectric 330. In this configuration, the upper surface of the first top gate dielectric 330 may be planar and located over the top surfaces of the source and drain electrodes (332, 338). For example, the first top gate dielectric 330 may be formed with a greater thickness than the thickness of the first source and drain electrodes (332, 338) followed by planarization by CMP or another method.

Referring to FIG. 14J, another alternative configuration of the exemplary structure is illustrated, which can be derived from the exemplary structure illustrated in FIG. 14F or FIG. 14I by laterally offsetting the first bottom gate electrode 315 from the inner edges of the source and drain electrodes (332, 338) by a lateral offset distance D1 in each thin film transistor 400. Such thin film transistors may be used in high voltage switching circuits.

Referring to FIG. 14K, another alternative configuration of the exemplary structure is illustrated, which can be derived from the exemplary structure illustrated in FIG. 14F or FIG. 14I by laterally overlapping the first bottom gate electrode 315 with the inner edges of the source and drain electrodes (332, 338) by a lateral overlap distance D2 in each thin film transistor 400. Such thin film transistors may be used in high speed circuits.

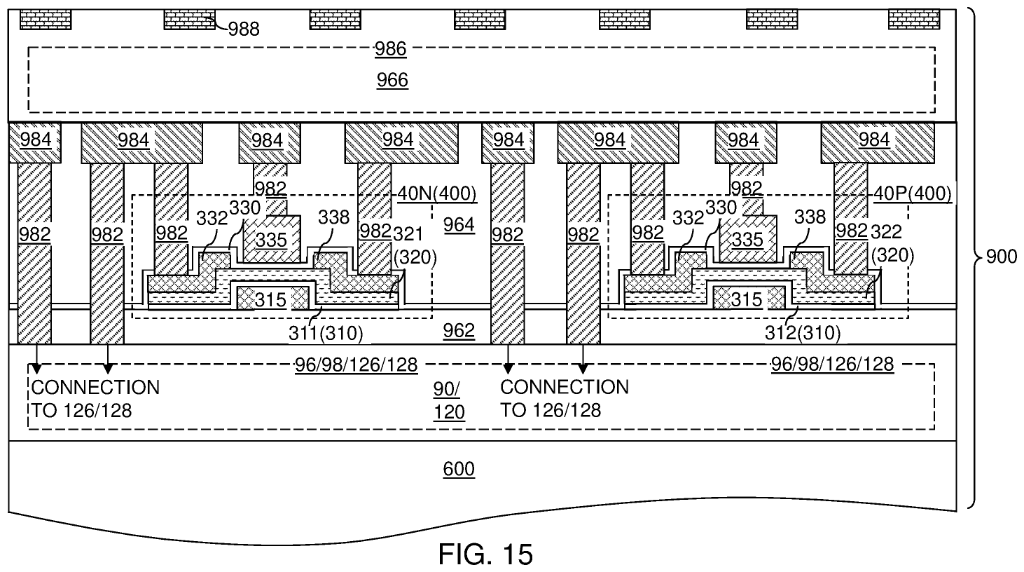

Referring to FIG. 15, another alternative configuration of the exemplary structure is illustrated, which can be derived from the exemplary structure illustrated in FIG. 14H by omitting formation of the second planar dielectric spacer layer 962, the second thin film transistors 420, and the third metal interconnect structures (992, 994). Generally speaking, the total device level in which thin film transistors (400, 420) are formed may be 2 as illustrated in FIG. 14H, 1 as illustrated in FIG. 15, or 3 or more in alternative embodiments.

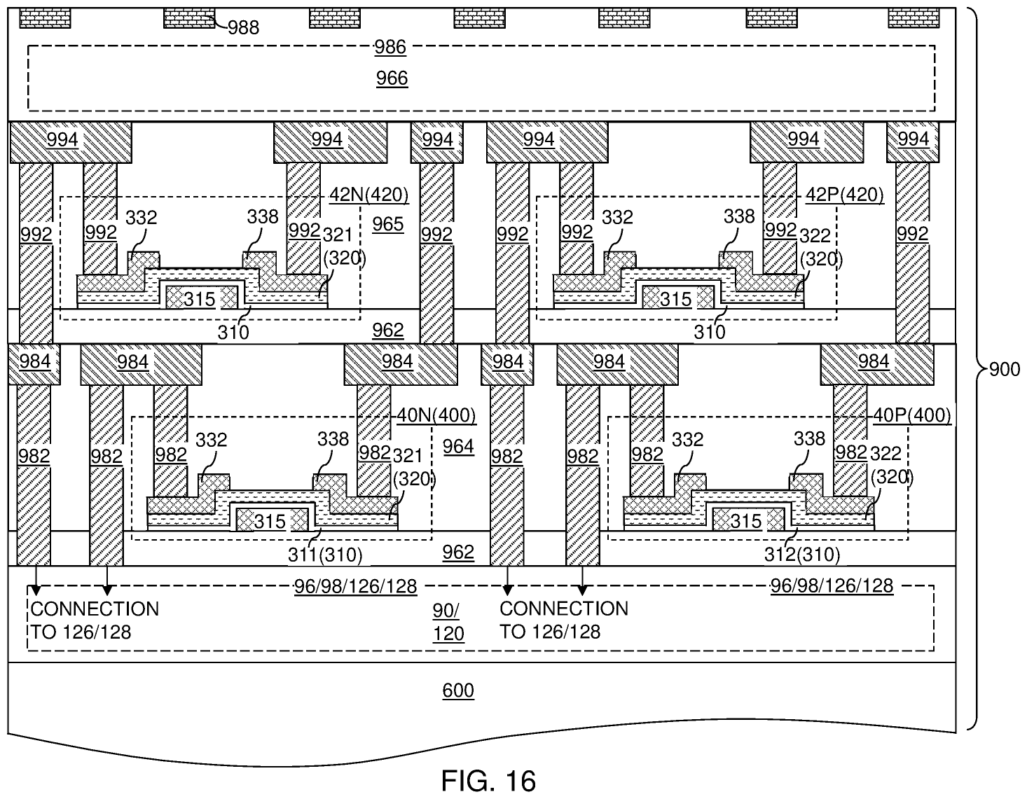

Referring to FIG. 16, another alternative configuration of the exemplary structure can be derived from the exemplary structure illustrated in FIG. 14H by forming the first thin film transistors 400 and/or the second thin film transistors 420 as thin film transistors employing a single gate electrode, which may be a bottom gate electrode 315 or a top gate electrode 335.

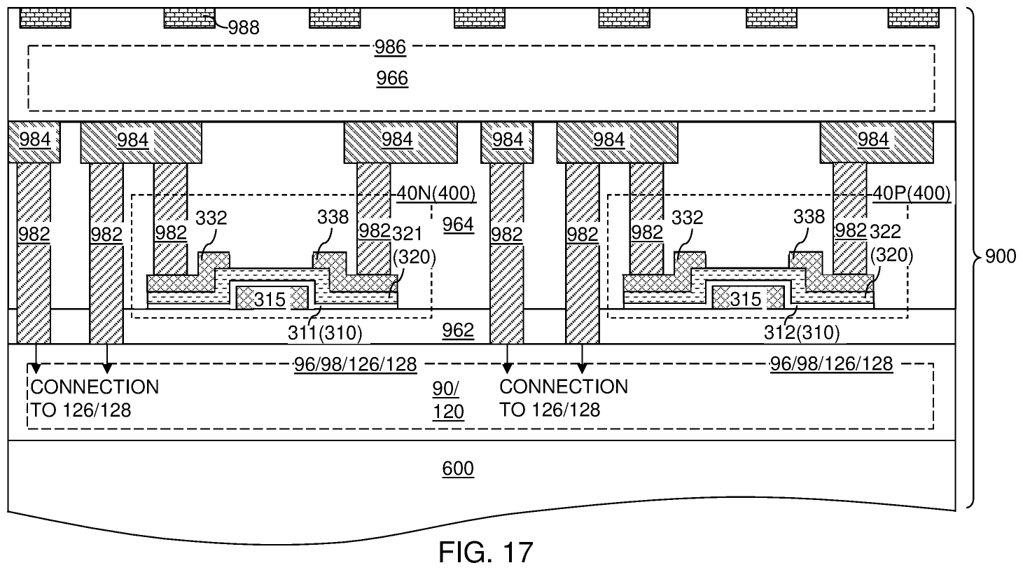

Referring to FIG. 17, another alternative configuration of the exemplary structure is illustrated, which can be derived from the second alternative configuration of the exemplary structure illustrated in FIG. 16 by omitting formation of the second planar dielectric spacer layer 962, the second thin film transistors 420, and the second metal interconnect structures (992, 994). Generally speaking, the total device level in which thin film transistors (400, 420) are formed may be 2 as illustrated in FIGS. 14H and 16, 1 as illustrated in FIGS. 15 and 17, or 3 or more in alternative embodiments.

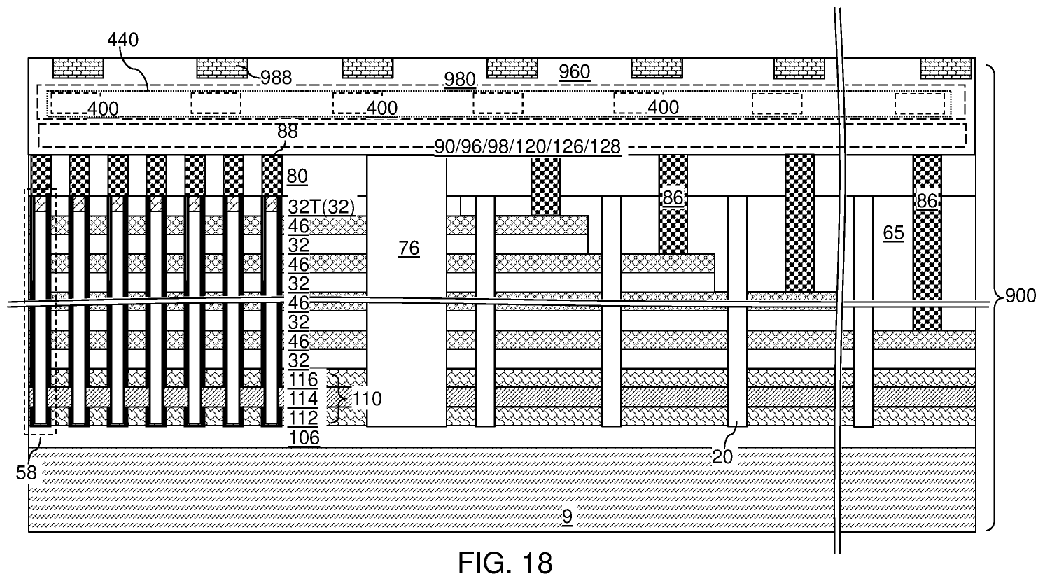

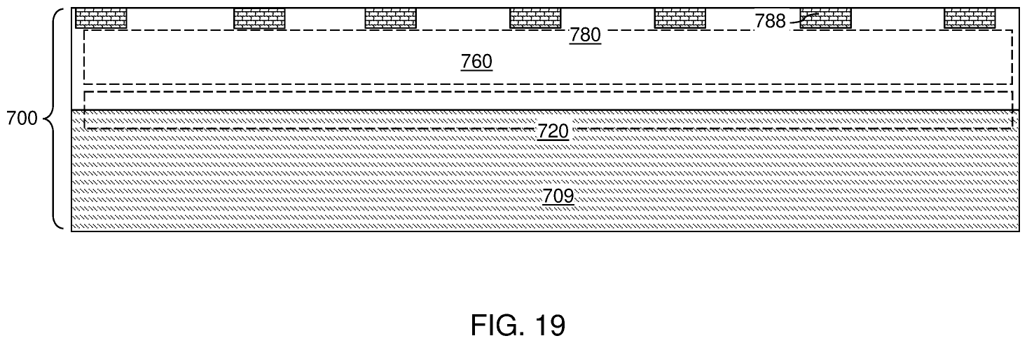

Referring to FIG. 18, a memory die 900 in various configurations of the exemplary structure is illustrated after performing the processing steps described with reference to FIGS. 14H, 15, 16, and 17. The combination of the second dielectric material layers 964, the third dielectric material layers 965, and the memory-side dielectric material layers 966 is represented as a set of dielectric material layers 960. The combination of the second metal interconnect structures (982, 984), third metal interconnect structures (992, 994), and the memory-side metal interconnect structures 986 is represented as a set of metal interconnect structures 980.

Generally, a first peripheral circuit 440 comprising the first thin film transistors 400 and an optional peripheral circuit comprising the second thin film transistors 420 (if present) and at least one additional optional peripheral circuit comprising additional thin film transistors (if present) may be provided in the memory die 900, The first peripheral circuit 440 may comprise a word line switching and/or row decoder circuit which is configured to control the operation of the electrically conductive layers 46 (e.g., to switch the word lines on and off).

Referring to FIG. 19, a logic die 700 is provided. The logic die 700 comprises a peripheral circuit 720 that is formed on a logic-side substrate 709. According to an aspect of the present disclosure, the peripheral circuit 720 can be configured to control operation of the memory array within the memory die 900. For example, the peripheral circuit 720 may comprise bit line driver, sense amplifier, data latch and/or input/output buffer circuits.

The peripheral circuit 720 in the logic die 700 may comprise a second peripheral circuit configured to control the operation of the bit lines 128 in the memory die 900 (i.e., to switching the bit lines 128 on and off). The second peripheral circuit 720 may comprise field effect transistors including single crystalline semiconductor channels (such as single crystalline silicon channels). In one embodiment, the field effect transistors may be arranged in a CMOS configuration. Logic-side metal interconnect structures 780 embedded within logic-side dielectric material layers 760 can be formed over the peripheral circuit 720. The logic die 700 comprises logic-side bonding pads 788 embedded within logic-side dielectric material layers 760.

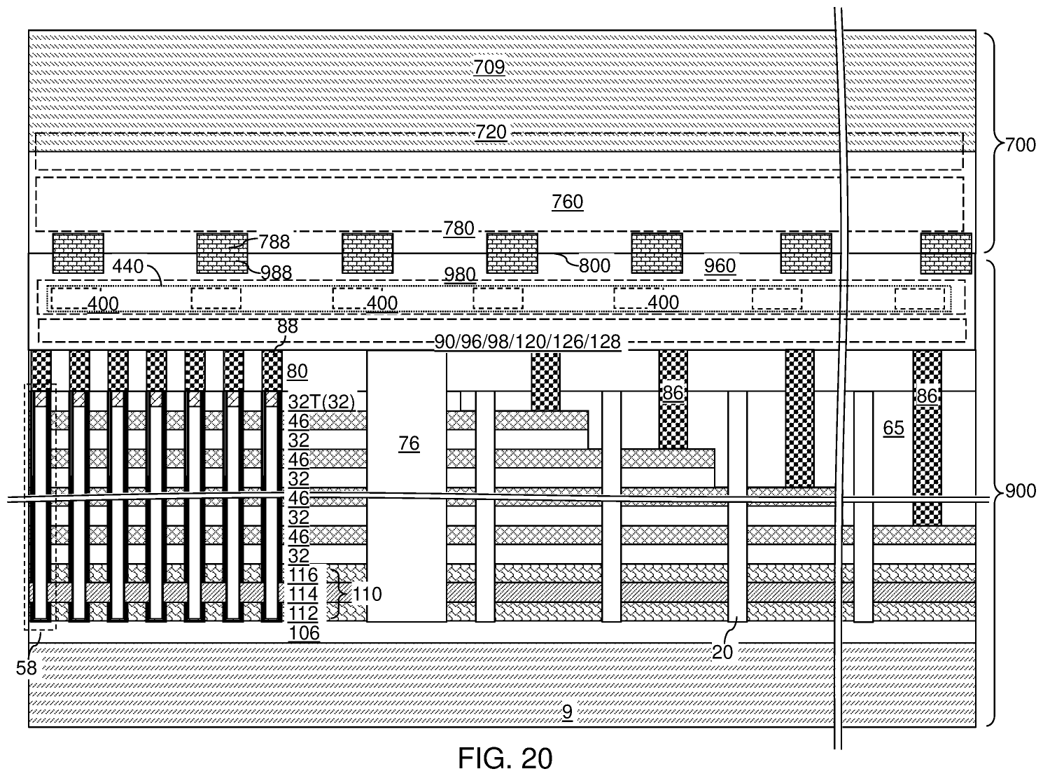

Referring to FIG. 20, a bonded assembly can be formed by bonding the logic die 700 with the memory die 900. The logic die 700 can be attached to the memory die 900, for example, by bonding the logic-side bonding pads 788 to the memory-side bonding pads 988. The bonding between the memory die 900 and the logic die 700 may be performed employing a wafer-to-wafer bonding process in which a two-dimensional array of memory dies 900 is bonded to a two-dimensional array of logic dies 700, by a die-to-bonding process, or by a die-to-die bonding process. The logic-side bonding pads 788 within each logic die 700 can be bonded to the memory-side bonding pads 988 within a respective memory die 900.

The logic die 700 can be attached to the memory die 900, for example, by bonding the logic-side bonding pads 788 to the memory-side bonding pads 988 at a bonding interface 800. The bonding between the memory die 900 and the logic die 700 may be performed employing a wafer-to-wafer bonding process in which a two-dimensional array of memory dies 900 is bonded to a two-dimensional array of logic dies 700, by a die-to-bonding process, or by a die-to-die bonding process. The logic-side bonding pads 788 within each logic die 700 can be bonded to the memory-side bonding pads 988 within a respective memory die 900 at the bonding interface between the logic die 700 and the memory die 900.

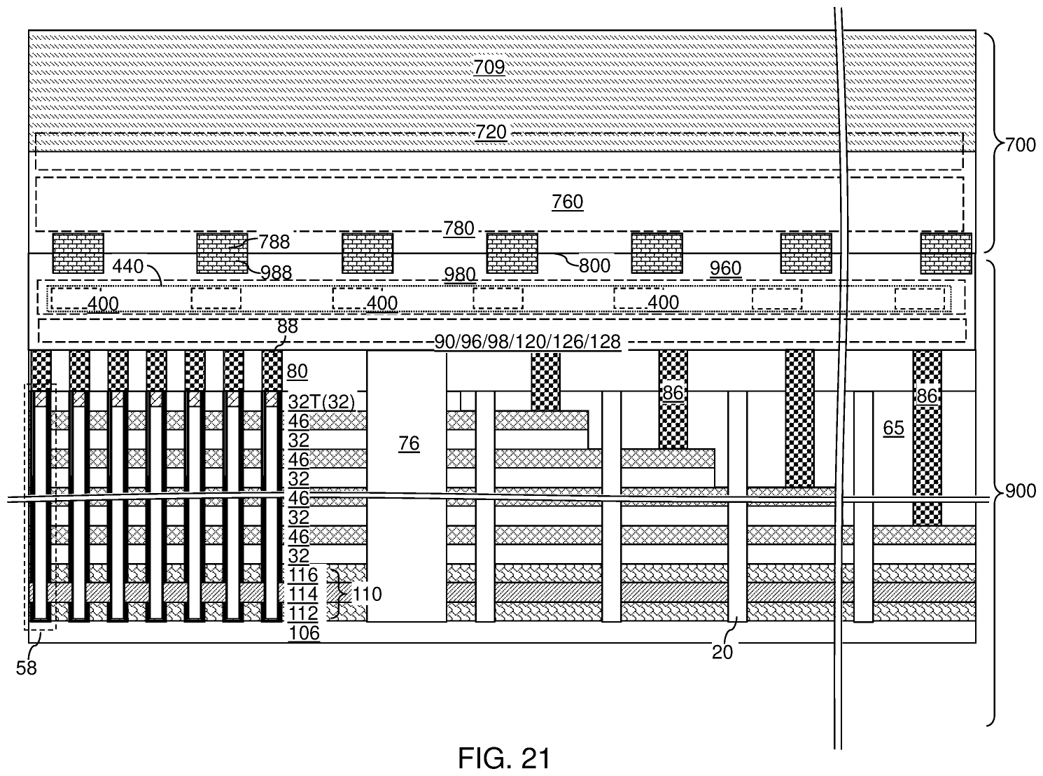

Referring to FIG. 21, the carrier substrate 9 can be optionally removed, for example, by grinding, polishing, cleaving, an isotropic etch process, and/or an anisotropic etch process. If a polishing process such as a chemical mechanical polishing process is employed to remove the carrier substrate 9, the stopper insulating layer 106 may be subsequently employed as a polishing stopper material layer. If an etch process such as a wet etch process is employed to remove the carrier substrate 9, the stopper insulating layer 106 may be subsequently employed as an etch stop material layer.

Referring to all drawings and according to various embodiments of the present disclosure, a semiconductor structure includes a memory die 900 and a logic die 700. The memory die 900 includes a three-dimensional memory device 600 that contains an alternating stack of insulating layers 32 and electrically conductive layers 46, memory openings 49 vertically extending through the alternating stack, and memory opening fill structures 58 located in the two-dimensional array of memory openings 49, where each of the memory opening fill structures 58 includes a respective vertical semiconductor channel 60, a respective drain region 63, and a vertical stack of memory elements (e.g., portions of the memory film 50) located at levels of the electrically conductive layers 46, memory-side bonding pads 988, and a first peripheral circuit 440 including first thin film transistors 400 located between the three-dimensional memory device 600 and the memory-side bonding pads 988. The logic die 700 includes a logic-side substrate 709, logic-side bonding pads 788 bonded to the memory-side bonding pads 988, and a second peripheral circuit 720 located between the logic-side substrate 709 and the logic-side bonding pads 788.

The various embodiments of the present disclosure can be employed to form thin film transistors (400, 420) over a three-dimensional memory device 600 within a memory die 900. The thin film transistors (400, 420) can be employed as components of a first peripheral circuit 440 that is configured to control operation of the three-dimensional memory device 600. A logic die 700 including a second peripheral circuit 720 can be bonded to the memory die 900. The combination of the first peripheral circuit and the second peripheral circuit can be employed to control the operation of the three-dimensional memory device 600.

Specifically, since the word line switching circuit (e.g. the first peripheral circuit 440) may have a large area footprint, it may cause the logic die 700 to have a larger surface area than the memory die 900. By forming the word line switching circuit over the memory die 900, the surface area of the logic die is reduced. The word line switching circuit may include TFTs (400, 420) formed at a low temperature (e.g., at 600 degrees Celsius or less, such as less than 400 degrees Celsius) to avoid damaging the memory device 600 during a high temperature deposition step. In contrast, the bit line control circuitry of the second peripheral circuit 720 may be formed at a high temperature on a high quality single crystal silicon substrate 709 to form high speed transistors. The high speed transistors of the logic die 700 are bonded to the memory die 900 after fabrication of the memory die 900 at a relatively low bonding temperature to avoid damage to the memory device 600.

Although the foregoing refers to particular preferred embodiments, it will be understood that the disclosure is not so limited. It will occur to those of ordinary skill in the art that various modifications may be made to the disclosed embodiments and that such modifications are intended to be within the scope of the disclosure. Compatibility is presumed among all embodiments that are not alternatives of one another. The word “comprise” or “include” contemplates all embodiments in which the word “consist essentially of” or the word “consists of” replaces the word “comprise” or “include,” unless explicitly stated otherwise. Whenever two or more elements are listed as alternatives in a same paragraph of in different paragraphs, a Markush group including a listing of the two or more elements is also impliedly disclosed. Whenever the auxiliary verb “can” is employed in this disclosure to describe formation of an element or performance of a processing step, an embodiment in which such an element or such a processing step is not performed is also expressly contemplated, provided that the resulting apparatus or device can provide an equivalent result. As such, the auxiliary verb “can” as applied to formation of an element or performance of a processing step should also be interpreted as “may” or as “may, or may not” whenever omission of formation of such an element or such a processing step is capable of providing the same result or equivalent results, the equivalent results including somewhat superior results and somewhat inferior results. Where an embodiment employing a particular structure and/or configuration is illustrated in the present disclosure, it is understood that the present disclosure may be practiced with any other compatible structures and/or configurations that are functionally equivalent provided that such substitutions are not explicitly forbidden or otherwise known to be impossible to one of ordinary skill in the art. If publications, patent applications, and/or patents are cited herein, each of such documents is incorporated herein by reference in their entirety.

What is claimed is:

1. A semiconductor structure, comprising:
a memory die, comprising:
a three-dimensional memory device that comprises an alternating stack of insulating layers and electrically conductive layers, memory openings vertically extending through the alternating stack, and memory opening fill structures located in the two-dimensional array of memory openings, wherein each of the memory opening fill structures comprises a respective vertical semiconductor channel, a respective drain region, and a vertical stack of memory elements located at levels of the electrically conductive layers;
memory-side bonding pads; and
a first peripheral circuit comprising first thin film transistors located between the three-dimensional memory device and the memory-side bonding pads; and
a logic die, comprising:
a logic-side substrate;
logic-side bonding pads bonded to the memory-side bonding pads; and
a second peripheral circuit located between the logic-side substrate and the logic-side bonding pads.

2. The semiconductor structure of claim 1, wherein the memory die further comprises:
first metal interconnect structures embedded within first dielectric material layers that overlie the three-dimensional memory device and electrically connected to a respective node within the three-dimensional memory device; and
the first thin film transistors are located over the first dielectric material layers and electrically connected to a respective electrical node within the three-dimensional memory device through a respective subset of the first metal interconnect structures.

3. The semiconductor structure of claim 2, wherein:
the first peripheral circuit comprises at least one of a word line switching circuit or a word line decoder circuit;
the first thin film transistors are electrically connected to a subset of the electrically conductive layers which function as word lines;
the first metal interconnect structures comprise bit lines that are laterally spaced apart from each other along a first horizontal direction and electrically connected to a respective subset of the drain regions; and
the second peripheral circuit comprises sense amplifiers that are electrically connected to a respective one of the bit lines.

4. The semiconductor structure of claim 2, further comprising a planar dielectric spacer layer interposed between the first dielectric material layers and first thin film transistors, wherein each of the first thin film transistors comprises a respective first gate dielectric having a respective planar bottom surface that contacts a respective segment of a horizontal surface of the planar dielectric spacer layer.

5. The semiconductor structure of claim 4, wherein each of the first thin film transistors comprises:
a respective first bottom gate electrode contacting the planar dielectric spacer layer;
a respective first semiconductor channel that overlies the respective first gate dielectric;
a respective first source electrode contacting a first end portion of the respective first semiconductor channel; and
a respective first drain electrode contacting a second end portion of the respective first semiconductor channel.

6. The semiconductor structure of claim 5, wherein the first bottom gate electrode is laterally offset from inner edges of the first source electrode and the first drain electrode.

7. The semiconductor structure of claim 1, wherein each of the first thin film transistors comprises a respective first semiconductor channel that includes a non-single-crystalline semiconductor material.

8. The semiconductor structure of claim 7, wherein the non-single-crystalline semiconductor material comprises a semiconductor metal oxide material, a semiconductor organic metal halide perovskite material, or a two-dimensional semiconductor material exhibiting higher in-plane electrical conductivity than out-of-plane conductivity.

9. The semiconductor structure of claim 1, wherein:
a first subset of the first thin film transistors comprises a respective semiconductor channel including a first semiconductor channel material having a first conductivity type; and
a second subset of the first thin film transistors comprises a respective semiconductor channel including a second semiconductor channel material having a second conductivity type.

10. The semiconductor structure of claim 9, wherein:
the first subset of the first thin film transistors comprises n-type thin film transistors, and the first semiconductor channel material comprises a semiconductor metal oxide material; and
a second subset of the first thin film transistors comprises p-type thin film transistors and the second semiconductor channel material comprises a semiconductor organic metal halide perovskite material.

11. The semiconductor structure of claim 9, wherein:
the first subset of the first thin film transistors comprises n-type thin film transistors, and the first semiconductor channel material comprises a MoS₂ two-dimensional semiconductor material exhibiting higher in-plane electrical conductivity than out-of-plane conductivity; and
a second subset of the first thin film transistors comprises p-type thin film transistors and the second semiconductor channel material comprises a WS₂ two-dimensional semiconductor material exhibiting higher in-plane electrical conductivity than out-of-plane conductivity.

12. The semiconductor structure of claim 9, wherein:
the semiconductor structure further comprises second metal interconnect structures embedded within second dielectric material layers that overlie the first thin film transistors and providing electrical connection among the first thin film transistors; and
the first thin film transistors are electrically connected to the respective electrical node within the three-dimensional memory device via the second metal interconnect structures.

13. The semiconductor structure of claim 12, wherein the memory die further comprises:
second thin film transistors located over the second metal interconnect structures; and
third metal interconnect structures embedded within third dielectric material layers overlying the second thin film transistors,
wherein the second thin film transistors are electrically connected to a respective electrical node within the three-dimensional memory device through a respective subset of the third metal interconnect structures, a respective subset of the second metal interconnect structures, and a respective subset of the first metal interconnect structures.

14. The semiconductor structure of claim 1, wherein the memory die further comprises memory-side metal interconnect structures embedded within memory-side dielectric material layers that overlie the first thin film transistors, wherein a first subset of the memory-side metal interconnect structures is electrically connected to a respective one of the first thin film transistors to the memory-side bonding pads which are embedded in an upper portion of the memory-side dielectric material layers.

15. The semiconductor structure of claim 14, wherein:
the logic die further comprises logic-side metal interconnect structures embedded in logic-side dielectric material layers and electrically connected to a respective node of the second peripheral circuit; and
the logic-side bonding pads are embedded within the logic-side dielectric material layers and electrically connected to the logic-side metal interconnect structures.

16. A method of forming a semiconductor structure, comprising:
providing a memory die, comprising:
a three-dimensional memory device that comprises an alternating stack of insulating layers and electrically conductive layers, memory openings vertically extending through the alternating stack, and memory opening fill structures located in the two-dimensional array of memory openings, wherein each of the memory opening fill structures comprises a respective vertical semiconductor channel, a respective drain region, and a vertical stack of memory elements located at levels of the electrically conductive layers;
memory-side bonding pads; and
a first peripheral circuit comprising first thin film transistors located between the three-dimensional memory device and the memory-side bonding pads;
providing a logic die, comprising:
a logic-side substrate;
logic-side bonding pads; and
a second peripheral circuit located between the logic-side substrate and the logic-side bonding pads; and
bonding the logic side bonding pads to the memory-side bonding pads.

17. The method of claim 16, wherein the memory die further comprises:
first metal interconnect structures embedded within first dielectric material layers that overlie the three-dimensional memory device and electrically connected to a respective node within the three-dimensional memory device; and
the first thin film transistors are located over the first dielectric material layers and electrically connected to a respective electrical node within the three-dimensional memory device through a respective subset of the first metal interconnect structures.

18. The method of claim 16, wherein:
the first peripheral circuit comprises at least one of a word line switching circuit or a word line decoder circuit;
the first thin film transistors are electrically connected to a subset of the electrically conductive layers which function as word lines;
the first metal interconnect structures comprise bit lines that are laterally spaced apart from each other along a first horizontal direction and electrically connected to a respective subset of the drain regions; and
the second peripheral circuit comprises sense amplifiers that are electrically connected to a respective one of the bit lines.

19. The method of claim 16, wherein each of the first thin film transistors comprises a respective first semiconductor channel that includes a non-single-crystalline semiconductor material.

20. The method of claim 19, wherein the non-single-crystalline semiconductor material comprises a semiconductor metal oxide material, a semiconductor organic metal halide perovskite material, or a two-dimensional semiconductor material exhibiting higher in-plane electrical conductivity than out-of-plane conductivity.
